(19) United States
(12) Patent Application Publication
(10) Pub. No.: US 2024/0284659 A1
(43) Pub. Date: Aug. 22, 2024

(54) LATERAL SPLIT DIGIT LINE MEMORY ARCHITECTURES

(71) Applicant: Micron Technology, Inc., Boise, ID (US)

(72) Inventors: Lorenzo Fratin, Buccinasco (MI) (IT); Fabio Pellizzer, Boise, ID (US)

(21) Appl. No.: 18/440,460

(22) Filed: Feb. 13, 2024

Related U.S. Application Data
(60) Provisional application No. 63/447,546, filed on Feb. 22, 2023.

(51) Int. Cl. H10B 12/00; G11C 11/408; G11C 11/4094

(52) U.S. Cl. CPC H10B 12/485; G11C 11/4085; G11C 11/4094; H10B 12/03; H10B 12/482; H10B 12/488

(57) ABSTRACT

Methods, systems, and devices for lateral split digit line memory architectures are described. A memory array may include a first set of word line plates separated from a second set of word line plates by a pillar (e.g., that is configured as a digit line) that interact with the first and second set of word line plates. Further, the memory array may include a set of dielectric piers that are positioned between the pillars, where each dielectric pier contacts a first pillar and a second pillar. Additionally, the memory array may include a set of storage elements and a set of digit lines that are each coupled with a word line plate, a pillar, and a dielectric material that is positioned between each first and second pillar of the pairs of pillars.

### CROSS REFERENCE

The present Application for Patent claims priority to and the benefit of U.S. Provisional Application No. 63/447,546 by Fratin et al., entitled “LATERAL SPLIT DIGIT LINE MEMORY ARCHITECTURES,” filed Feb. 22, 2023, assigned to the assignee hereof, and is expressly incorporated by reference in its entirety herein.

### TECHNICAL FIELD

The following relates to one or more systems for memory, including lateral split digit line memory architectures.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a memory array that supports lateral split digit line memory architectures in accordance with examples as disclosed herein.

FIGS. 2A and 2B illustrate side views of an example of a memory array that supports lateral split digit line memory architectures in accordance with examples as disclosed herein.

FIGS. 3 through 15 illustrate an example of material arrangements that supports lateral split digit line memory architectures in accordance with examples as disclosed herein.

FIGS. 16 and 17 illustrate flowcharts showing a method or methods that support lateral split digit line memory architectures in accordance with examples as disclosed herein.

### DETAILED DESCRIPTION

The present disclosure relates to a memory device with a split digit line architecture, and methods of processing the same. The memory device may include an arrangement of conductive contacts and openings through alternative layers of conductive materials and insulative material that may decrease the spacing between the memory cells while maintaining a dielectric thickness to sustain the voltage to be applied to a memory array of the memory device.

In some examples, a memory device may include a substrate with a set of contacts arranged in a pattern (e.g., a geometric pattern). During a manufacturing of the memory device, a stack of layers may be formed over the substrate. For example, alternating layers of a nitride material (or another type of material that may be a sacrificial material) and a first dielectric material may be deposited over the substrate to form the stack of layers. In a first case (e.g., a trench and pier architecture), a trench may be formed through the stack of layers to expose the substrate. For example, a trench may be formed to divide the stack into two sections or sets of plates. After forming the trench, a set of dielectric piers (e.g., including a second dielectric material) may be formed along the trench. In a second case (e.g., a pillar and pier architecture), the set of dielectric piers may be formed without first forming a trench through the stack. For example, a set of cavities that extend through the stack of layers may be formed and the second dielectric material may be deposited into each of the set of cavities to form the set of dielectric piers. Then, a second set of cavities may be formed through the stack of layers that each extend through the stack of layers and expose the substrate. In this case, the second set of cavities may functionally divide the stack into two sections or sets of plates (e.g., similarly to the trench in the first case).

In either case, after forming the set of dielectric piers, the layers of the nitride material may be replaced with a conductive material to form word line plates. The word line plates may include a set of even word line plates that are separated (e.g., by either the trench or the set of other cavities) from a set of odd word line plates. Then, a set of dielectric pillars that extend through the stack of materials and contact the substrate may be formed between the set of dielectric piers, where each of the dielectric pillars includes a third dielectric material (e.g., an insulative pillar sheath) that surrounds a fourth dielectric material (e.g., a core dielectric material). A third set of cavities may be formed by removing the dielectric piers and portions of the pillar sheaths, and each dielectric pillar may have a first and second remaining portion of the pillar sheath. In some cases, the first portion of each remaining pillar sheath may mechanically couple each dielectric pillar to a first sidewall of the stack of materials and the second portion of each remaining pillar sheath may mechanically couple each dielectric pillar to a second sidewall of the stack of materials. After forming the third cavities, a set of conductive pillars (e.g., configured as digit lines or bit lines) may be formed by depositing a second conductive material into the set of third cavities. In some cases, each conductive pillar may contact sidewalls of a portion of the dielectric pillar sheath and sidewalls of the fourth dielectric material (e.g., associated with the core of a dielectric pillar). Then memory cells may be formed by depositing a memory material, and each memory cell may be coupled with one conductive pillar and one word line plate.

Such configurations of a memory device and the methods of manufacturing may allow a higher-density of memory cells relative to previous solutions. For example, the digit line and memory cell configuration, as described herein, may allow for a higher density of digit lines and memory cells with respect to some previous solutions. Similarly, the dielectric pier configuration and the portions of the dielectric pillar sheaths that couple the dielectric pillars with sidewalls of the stack of materials, as described herein, may result in improved stability or tolerances, such that subsequent formation of features (e.g., circuit structures, access lines, memory cells) may be performed with reduced variability or otherwise improved consistency, among other advantages. That is, the dielectric piers and the remaining portions of the dielectric pillar sheaths may be formed in contact with the cross sectional patterns such that, when other materials in the stack are removed (e.g., the nitride material in a replacement gate process, the dielectric piers, etc.), the dielectric piers or the remaining portions of the dielectric pillar sheaths provide mechanical support of the cross-sectional pattern of the remaining material.

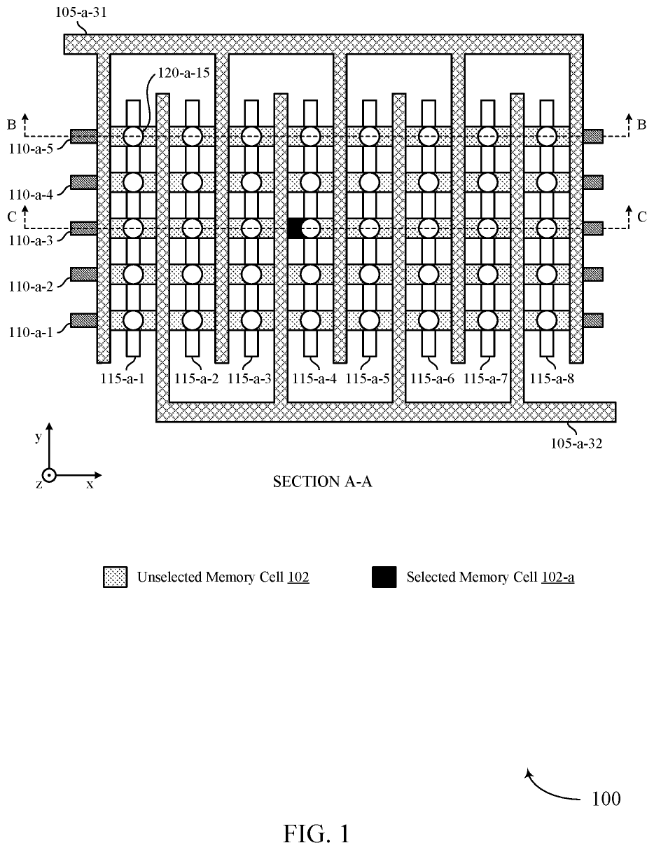

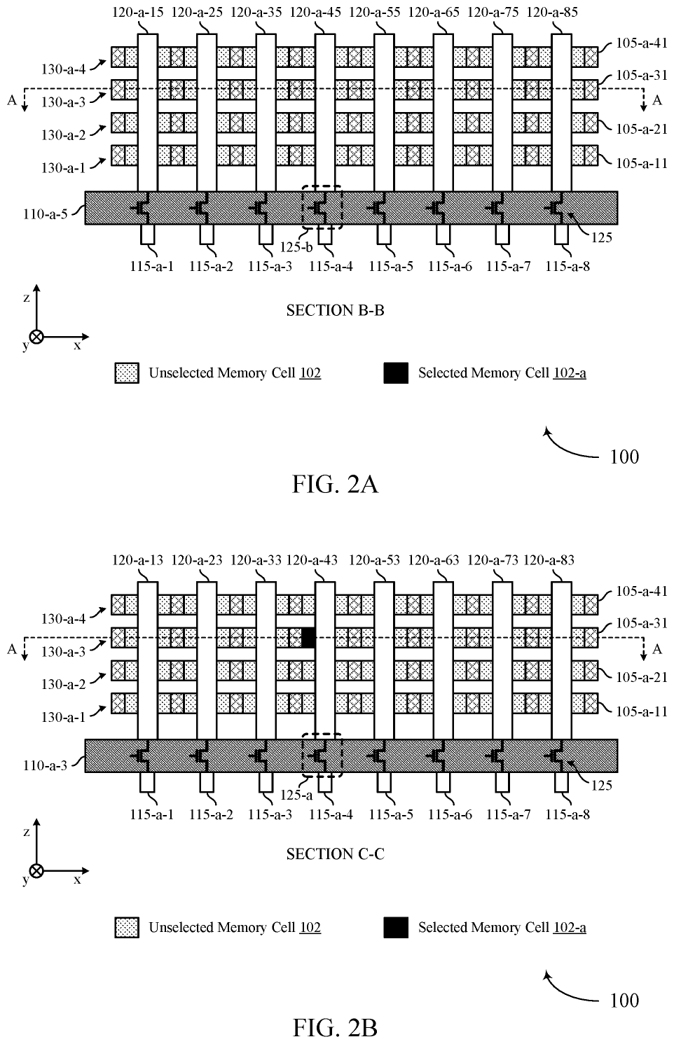

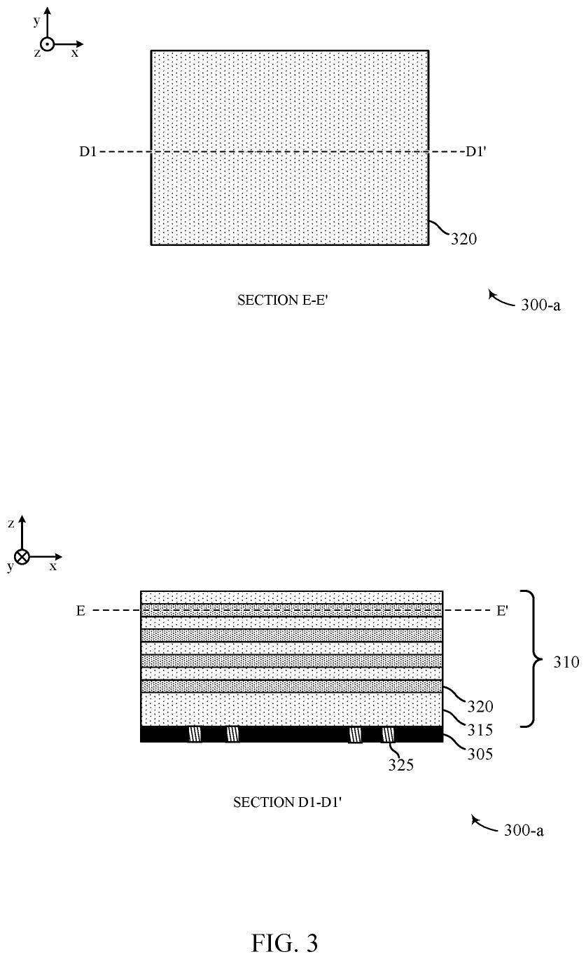

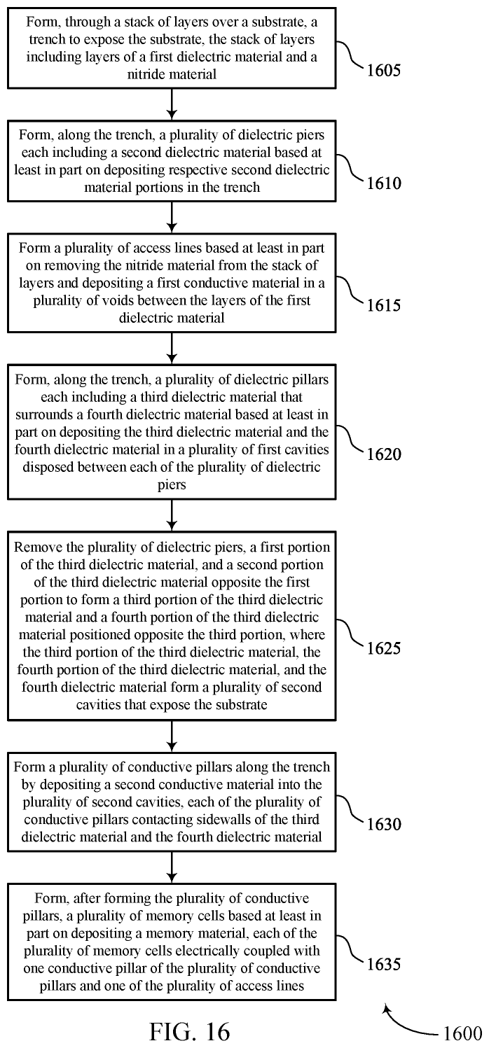

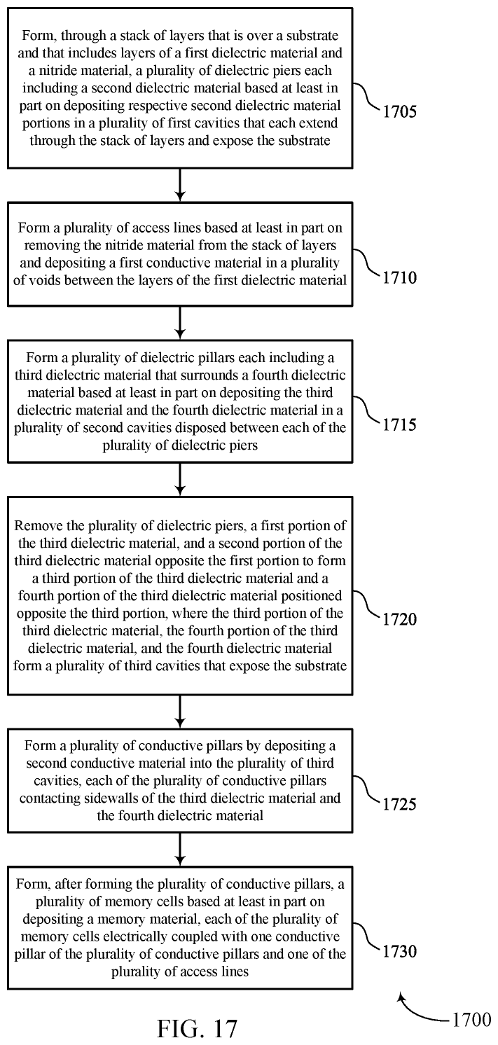

Features of the disclosure are initially described in the context of memory devices and arrays with reference to FIGS. 1, 2A and 2B. Features of the disclosure are described in the context of material arrangements with reference to FIGS. 3 through 15. These and other features of the disclosure are further illustrated by and described with reference to flowcharts that relate to lateral split digit line memory architectures as described with reference to FIGS. 16 and 17.

FIGS. 1, 2A, and 2B illustrate an example of a memory array 100 that supports lateral split digit line memory architectures in accordance with examples as disclosed herein. FIG. 1 illustrates a top section view (e.g., SECTION A-A) of the memory array 100 relative to a cut plane A-A as shown in FIGS. 2A and 2B. FIG. 2A illustrates a side section view (e.g., SECTION B-B) of the memory array 100 relative to a cut plane B-B as shown in FIG. 1. FIG. 2B illustrates a side section view (e.g., SECTION C-C) of the memory array 100 relative to a cut plane C-C as shown in FIG. 1. The section views may be examples of cross-sectional views of the memory array 100 with some aspects (e.g., dielectric structures) removed for clarity. Elements of the memory array 100 may be described relative to an x-direction, a y-direction, and a z-direction, as illustrated in each of FIGS. 1, 2A, and 2B. Although some elements included in FIGS. 1, 2A, and 2B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 100, techniques in accordance with examples as described herein may be applicable to any quantity of such elements, or ratios of quantities between one repeated element and another.

In the example of memory array 100, memory cells 102 and word lines 105 may be distributed along the z-direction according to levels 130 (e.g., decks, layers, planes, tiers, as illustrated in FIGS. 2A and 2B). In some examples, the z-direction may be orthogonal to a substrate (not shown) of the memory array 100, which may be below the illustrated structures along the z-direction. Although the illustrative example of memory array 100 includes four levels 130, a memory array 100 in accordance with examples as disclosed herein may include any quantity of one or more levels 130 (e.g., 64 levels, 128 levels) along the z-direction.

Each word line 105 may be an example of a portion of an access line that is formed by one or more conductive materials (e.g., one or more metal portions, one or more metal alloy portions). As illustrated, a word line 105 may be formed in a comb structure, including portions (e.g., projections, tines) extending along the y-direction through gaps (e.g., alternating gaps) between pillars 120. For example, as illustrated, the memory array 100, may include two word lines 105 per level 130 (e.g., according to odd word lines 105-a-n1 and even word lines 105-a-n2 for a given level, n), where such word lines 105 of the same level 130 may be described as being interleaved (e.g., with portions of an odd word line 105-a-n1 projecting along the y-direction between portions of an even word line 105-a-n2, and vice versa). In some examples, an odd word line 105 (e.g., of a level 130) may be associated with a first memory cell 102 on a first side (e.g., along the x-direction) of a given pillar 120 and an even word line (e.g., of the same level 130) may be associated with a second memory cell 102 on a second side (e.g., along the x-direction, opposite the first memory cell 102) of the given pillar 120. Thus, in some examples, memory cells 102 of a given level 130 may be addressed (e.g., selected, activated) in accordance with an even word line 105 or an odd word line 105.

Each pillar 120 may be an example of a portion of an access line (e.g., a conductive pillar portion) that is formed by one or more conductive materials (e.g., one or more metal portions, one or more metal alloy portions). As illustrated, the pillars 120 may be arranged in a two-dimensional array (e.g., in an xy-plane) having a first quantity of pillars 120 along a first direction (e.g., eight pillars along the x-direction, eight rows of pillars), and having a second quantity of pillars 120 along a second direction (e.g., five pillars along the y-direction, five columns of pillars). Although the illustrative example of memory array 100 includes a two-dimensional arrangement of eight pillars 120 along the x-direction and five pillars 120 along the y-direction, a memory array 100 in accordance with examples as disclosed herein may include any quantity of pillars 120 along the x-direction and any quantity of pillars 120 along the y-direction. Further, as illustrated, each pillar 120 may be coupled with a respective set of memory cells 102 (e.g., along the z-direction, one or more memory cells 102 for each level 130). A pillar 120 may have a cross-sectional area in an xy-plane that extends along the z-direction. Although illustrated with a circular cross-sectional area in the xy-plane, a pillar 120 may be formed with a different shape, such as having an elliptical, square, rectangular, polygonal, or other cross-sectional area in an xy-plane.

The memory cells 102 each may include a chalcogenide material. In some examples, the memory cells 102 may be examples of thresholding memory cells. Each memory cell 102 may be accessed (e.g., addressed, selected) according to an intersection between a word line 105 (e.g., a level selection, which may include an even or odd selection within a level 130) and a pillar 120. For example, as illustrated, a selected memory cell 102-a of the level 130-a-3 may be accessed according to an intersection between the pillar 120-a-43 and the word line 105-a-32.

A memory cell 102 may be accessed (e.g., written to, read from) by applying an access bias (e.g., an access voltage, V_{access}, which may be a positive voltage or a negative voltage) across the memory cell 102. In some examples, an access bias may be applied by biasing a selected word line 105 with a first voltage (e.g., V_{access}/2) and by biasing a selected pillar 120 with a second voltage (e.g., −V_{access}/2), which may have an opposite sign relative to the first voltage. Regarding the selected memory cell 102-a, a corresponding access bias (e.g., the first voltage) may be applied to the word line 105-a-32, while other unselected word lines 105 may be grounded (e.g., biased to OV). In some examples, a word line bias may be provided by a word line driver (not shown) coupled with one or more of the word lines 105.

To apply a corresponding access bias (e.g., the second voltage) to a pillar 120, the pillars 120 may be configured to be selectively coupled with a sense line 115 (e.g., a digit line, a column line, an access line extending along the y-direction) via a respective transistor 125 coupled between (e.g., physically, electrically) the pillar 120 and the sense line 115. In some examples, the transistors 125 may be vertical transistors (e.g., transistors having a channel along the z-direction, transistors having a semiconductor junction along the z-direction), which may be formed above the substrate of the memory array 100 using various techniques (e.g., thin film techniques).

The transistors 125 (e.g., a channel portion of the transistors 125) may be activated by gate lines 110 (e.g., activation lines, selection lines, a row line, an access line extending along the x-direction) coupled with respective gates of a set of the transistors 125 (e.g., a set along the x-direction). In other words, each of the pillars 120 may have a first end (e.g., towards the negative z-direction, a bottom end) configured for coupling with an access line (e.g., a sense line 115). In some examples, the gate lines 110, the transistors 125, or both may be considered to be components of a row decoder (e.g., as pillar decoder components). In some examples, the selection of (e.g., biasing of) pillars 120, or sense lines 115, or various combinations thereof, may be supported by a column decoder, or a sense component, or both.

To apply the corresponding access bias (e.g., −V_{access}/2) to the pillar 120-a-43, the sense line 115-a-4 may be biased with the access bias, and the gate line 110-a-3 may be grounded (e.g., biased to 0V) or otherwise biased with an activation voltage. In an example where the transistors 125 are n-type transistors, the gate line 110-a-3 being biased with a voltage that is relatively higher than the sense line 115-a-4 may activate the transistor 125-a(e.g., cause the transistor 125-a to operate in a conducting state), thereby coupling the pillar 120-a-43 with the sense line 115-a-4 and biasing the pillar 120-a-43 with the associated access bias. However, the transistors 125 may include different channel types, or may be operated in accordance with different biasing schemes, to support various access operations.

In some examples, unselected pillars 120 of the memory array 100 may be electrically floating when the transistor 125-a is activated, or may be coupled with another voltage source (e.g., grounded, via a high-resistance path, via a leakage path) to avoid a voltage drift of the pillars 120. For example, a ground voltage being applied to the gate line 110-a-3 may not activate other transistors coupled with the gate line 110-a-3, because the ground voltage of the gate line 110-a-3 may not be greater than the voltage of the other sense lines 115 (e.g., which may be biased with a ground voltage or may be floating). Further, other unselected gate lines 110, including gate line 110-a-5 as shown in FIG. 2A, may be biased with a voltage equal to or similar to an access bias (e.g., −V_{access}/2, or some other negative bias or bias relatively near the access bias voltage), such that transistors 125 along an unselected gate line 110 are not activated. Thus, the transistor 125-b coupled with the gate line 110-a-5 may be deactivated (e.g., operating in a non-conductive state), thereby isolating the voltage of the sense line 115-a-4 from the pillar 120-a-45, among other pillars 120.

In some examples, a memory device (e.g., including one or more memory arrays 100) may include a substrate with a set of contacts arranged in a pattern (e.g., a geometric pattern). During a manufacturing of the memory device, a stack of layers may be formed over the substrate. For example, alternating layers of a nitride material (or another type of material that may be a sacrificial material) and a first dielectric material may be deposited over the substrate to form the stack of layers. In a first case, a trench may then be formed through the stack of layers to expose the substrate. For example, a trench may be formed to divide the stack into two sections or sets of plates. After forming the trench, a set of dielectric piers (e.g., including a second dielectric material) may be formed along the trench. In a second case, the set of dielectric piers may be formed without first forming a trench through the stack. For example, a set of cavities that extend through the stack of layers may be formed, and the second dielectric material may be deposited into each of the set of cavities to form the set of dielectric piers. Then, a second set of cavities may be formed through the stack of layers that each extend through the stack of layers and expose the substrate. In this case, the second set of cavities may functionally divide the stack into two sections or sets of plates (e.g., similarly to the trench in the first case).

In either case, after forming the set of dielectric piers, the layers of the nitride material may be replaced with a conductive material to form word line plates. The word line plates may include a set of even word line plates that are separated (e.g., by either the trench or the set of other cavities) from a set of odd word line plates. Then, a set of conductive pillars 120 that contact the substrate may be formed between the set of dielectric piers. For example, a second conductive material may be conformally deposited on sidewalls of cavities that extend between the dielectric piers and a third dielectric material may be deposited into the cavities. An insulative material may be deposited on sidewalls of the cavities (e.g., on the third dielectric material, on the dielectric piers) to form insulative pillar sheaths. A fourth dielectric may be deposited into the cavities to form the conductive pillars 120 (e.g., each surrounded by a pillar sheath). A third set of cavities may be formed by removing the dielectric piers and portions of the pillar sheaths, and a fourth dielectric may be deposited within portions of the third cavities. The fourth dielectric may be partially removed such that a conductive material (e.g., similar to the second conductive material) may be deposited within the third cavities to form digit lines (e.g., each digit line may be partially surrounded by the fourth dielectric material). Portions of the third dielectric material may be removed to form voids, and memory cells may be formed within the set of voids, where each void is defined by one of the pillars 120, a word line plate, and adjacent layers of the third dielectric material. As such, the resulting materials associated with each pillar 120 may include two divided digit lines (e.g., four total digit lines) and four memory cells for each pillar 120.

FIGS. 3 through 15 illustrate examples of fabrication operations that may support lateral split digit line memory architectures in accordance with examples as disclosed herein. For example, FIGS. 3 through 15 may illustrate operations for fabricating aspects of a material arrangement 300, which may be a portion of a memory device (e.g., a portion of a memory array 100, a portion of a memory die). Each of FIGS. 3 through 15 may illustrate aspects of the material arrangement 300 after different subsets of or alternatives of the fabrication operations for forming the material arrangement 300 (e.g., illustrated as a material arrangement 300-a after a first set of one or more manufacturing operations, as a material arrangement 300-b after a second set of one or more manufacturing operations, and so on). Each view of FIGS. 3 through 15 may be described with reference to an x-direction, a y-direction, and a z-direction, as illustrated, which may correspond to the respective directions described with reference to the memory array 100.

Each of FIGS. 3 through 15 include section views that illustrate example cross-sections of the material arrangement 300. For example, in FIGS. 3 through 15, a view “SECTION E-E” may be associated with a cross-section in an xy-plane (e.g., in accordance with a cut plane E-E′) through a portion of the material arrangement 300 that is associated with word lines 105 and memory cells 102 (e.g., an active level, a level 130), a view “SECTION F-F′” may be associated with a cross-section in an xy-plane (e.g., in accordance with a cut plane F-F′) through a portion of the material arrangement 300 that is associated with word lines 105 and memory cells 102 (e.g., an active level, a level 130), a view “SECTION D1-D1′” may be associated with a cross-section in an xz-plane (e.g., in accordance with a cut plane D1-D1′) through a portion of the material arrangement 300 that is associated with conductive pillars (e.g., pillars 120), a view “SECTION D2-D2′” may be associated with a cross-section in an xz-plane (e.g., in accordance with a cut plane D2-D2′) through a portion of the material arrangement 300 that is associated with piers (e.g., structural piers, dielectric piers), and a view “SECTION D3-D3′” may be associated with a cross-section in an xz-plane (e.g., in accordance with a cut plane D3-D3′) through a portion of the material arrangement 300 that is associated with conductive pillars (e.g., pillars 120). Although the material arrangement 300 illustrates examples of certain relative dimensions and quantities of various features, aspects of the material arrangement 300 may be implemented with other relative dimensions or quantities of such features in accordance with examples as disclosed herein.

Operations illustrated in and described with reference to FIGS. 3 through 15 may be performed by a manufacturing system, such as a semiconductor fabrication system configured to perform additive operations such as deposition or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 3 illustrates an example of a material arrangement 300 (e.g., as a material arrangement 300-a) after a first set of one or more manufacturing operations that support lateral split digit line memory architectures in accordance with examples as disclosed herein. The first set of operations may include depositing a stack of layers 310 over a substrate 305. The substrate 305 may be a semiconductor wafer or other substrate over which the stack of layers 310 is deposited. The substrate 305 may include one or more conductive contacts 325 within a same cavity. The conductive contacts 325 may be in direct contact with the substrate 305, and may be used as an interconnection between various elements (e.g., the substrate 305, various access lines, various pillars, access circuitry) of the material arrangement 300. Although the stack of layers 310 is illustrated as being deposited in direct contact with the substrate 305 and associated conductive contacts 325, in some other examples, the material arrangement 300 may include other materials or components between the stack of layers 310 and the substrate 305 (e.g., and conductive contacts 325), such as interconnection or routing circuitry (e.g., access lines, sense lines, gate lines), control circuitry (e.g., transistors, aspects of a local memory controller, decoders, multiplexers), or another stack of layers 310 (e.g., another stack of layers 310 has been processed in accordance with examples as disclosed herein), which may include various conductor, semiconductor, or dielectric materials between the stack of layers 310 and the substrate 305. For example, the material arrangement 300 may include a layer including thin-film-transistors (TFT) between the substrate 305 and the stack of layers 310, such as transistors, among others. In some examples, the substrate 305 itself may include such interconnection or routing circuitry.

The stack of layers 310 may include alternating layers of a material 315 (e.g., a first material) and a material 320 (e.g., a second material), which may be formed at least in part using alternating material deposition operations. In some examples, the material 315 may include a dielectric material (e.g., a first dielectric material), such as an oxide (e.g., a tier oxide, an oxide of silicon), and may provide electrical isolation between levels. The material 320 may include various materials that are different than the material 315, which may support differential processing (e.g., differential etching, high selectivity). For example, the layers of the material 320 may be sacrificial layers (e.g., a material that may not be present in a completed portion of the material arrangement 300). In some examples, the material 320 may be a nitride material (e.g., a tier nitride, a nitride of silicon). Although the stack of layers 310 is illustrated with nine layers (e.g., five layers of the material 315 and four layers of the material 320), a stack of layers 310 in accordance with examples as disclosed herein may include any quantity of layers of each of two or more materials (e.g., tens of layers, hundreds of layers, and so on), with either the material 315 or the material 320 being relatively closest to the substrate 305.

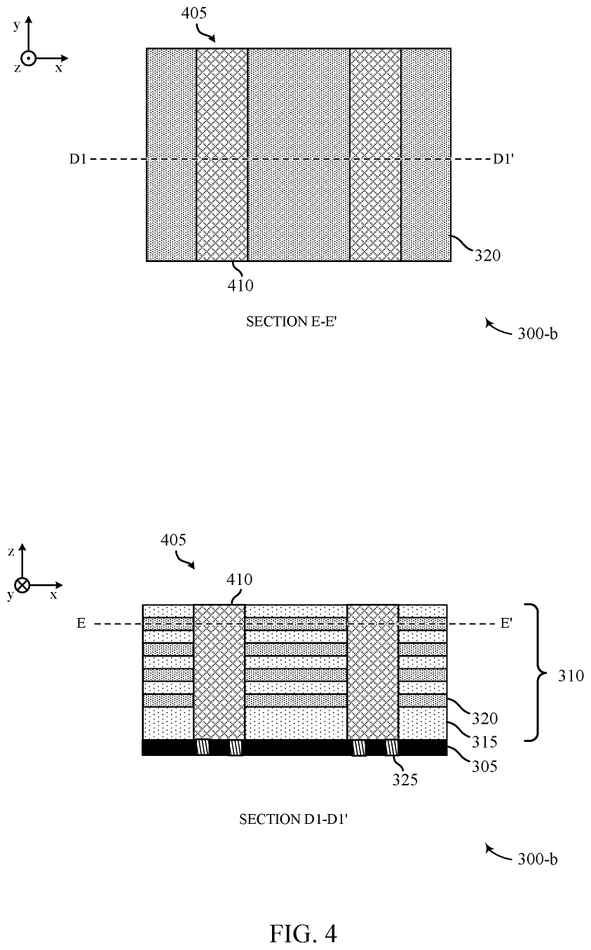

FIG. 4 illustrates an example of a material arrangement 300 (e.g., as a material arrangement 300-b) after a first alternative including a second set of one or more manufacturing operations that support lateral split digit line memory architectures in accordance with examples as disclosed herein. In some cases, these second set of manufacturing operations may be performed on the material arrangement 300-a to form the material arrangement 300-b. The second set of operations may include operations (e.g., a trench etch operation) that support forming trenches 405 through the stack of layers 310 (e.g., by removing portions of the material 315 and the material 320 along the z-direction, to the substrate 305 and associated conductive contacts 325 or to an intervening material between the stack of layers 310 and the substrate 305). In some examples, forming the trenches 405 may involve depositing and patterning a masking material (e.g., above the stack of layers 310, not shown), which may be followed by an etching operation (e.g., a dry etching operation, such as reactive ion etching (RIE), that supports material removal that is preferentially directional along the z-direction). The trenches 405 may extend along the y-direction, and may correspond to an isolation region of a memory array that is located between access lines (e.g., between word lines, or projections thereof, along the y-direction). In some examples, the trenches 405 may be aligned along a direction of pillars. For example, sidewalls of the trenches 405 may coincide with sidewalls of pillars that are formed in later operations, such that sidewalls of the trenches 405 may provide an alignment between pillars, among other features of material arrangement 300, to support operation as a memory array (e.g., to improve array density, to reduce a likelihood of misaligned features).

The second set of operations may also include operations (e.g., a trench fill operation) that includes depositing a material 410 (e.g., one or more third materials) in the trenches 405. The material 410 may be a nitride material and may be referred to as a sacrificial material. In some examples, the material 410 may be the same as the material 320 (e.g., a sacrificial material, a nitride material). In some other examples, the material 410 may be different than the material 315 and the material 320, which may support aspects of material removal differentiation (e.g., selectivity) among the material 315, the material 320, and the material 410. In some examples, the second set of operations may include planarization operation (e.g., a polishing operation, a chemical-mechanical planarization (CMP) operation) to flatten a top surface of the material arrangement 300-b, which may support aspects of subsequent operations.

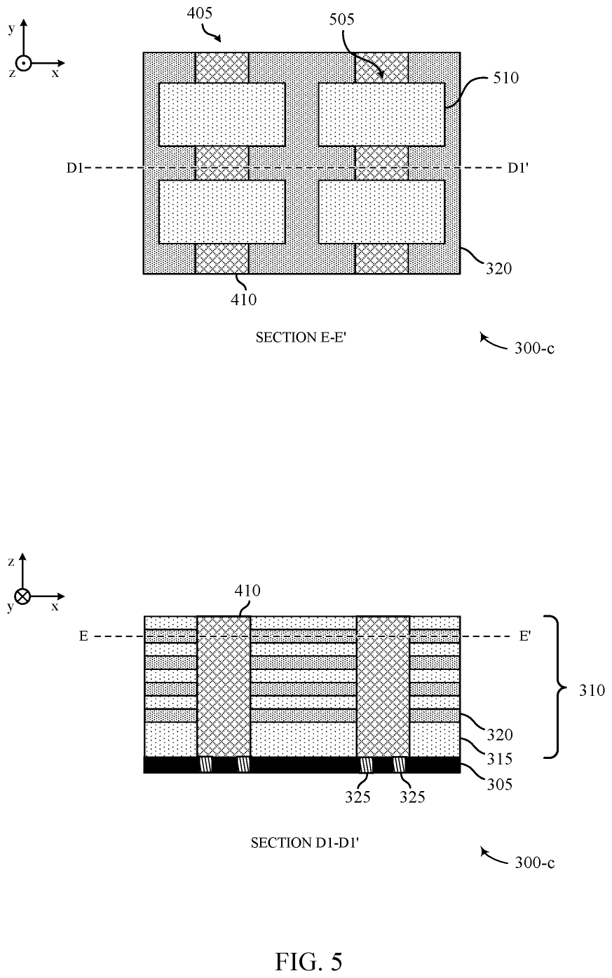

FIG. 5 illustrates an example of a material arrangement 300 (e.g., as a material arrangement 300-c) after a third set of one or more manufacturing operations included in the first alternative that support lateral split digit line memory architectures in accordance with examples as disclosed herein. The third set of manufacturing operations may be performed on the material arrangement 300-b to form the material arrangement 300-c. The third set of operations may include operations (e.g., a pier etch operation) that support forming a set of piers 505 (e.g., dielectric piers). To form the piers 505, the third set of operations may include forming cavities (e.g., that are subsequently filled to create the dielectric piers 505) based on removing portions of the material 410 (e.g., along the z-direction, to the substrate 305, conductive contacts 325, or to an intervening material between the stack of layers 310 and the substrate 305). In some examples, forming each cavity may expose a respective first sidewall of the stack of layers 310 on a first side of each cavity (e.g., along the x-direction) and a respective second sidewall of the stack of layers 310 on a second side of the cavity (e.g., along the x-direction). In some examples, forming the cavities may also include removing portions of the material 315 and the material 320 (e.g., along the z-direction, to the substrate 305 or to an intervening material between the stack of layers 310 and the substrate 305), such as when the cavities are formed to be wider, along the x-direction, than the trenches 405. In various examples, the cavities may be wider than trenches 405 to support a degree of misalignment between patterning for the cavities and the trenches 405 (e.g., along the x-direction), or to support forming projections of the material 315 and the material 320 between the cavities (e.g., along the x-direction, for formation of memory cells), or both, among other reasons. In some examples, forming the cavities may involve depositing and patterning a masking material (e.g., above the stack of layers 310 and material 410, not shown), which may be followed by an etching operation (e.g., a dry etching operation, such as RIE, that supports material removal that is preferentially directional along the z-direction).

The third set of operations may also include operations (e.g., a pier fill operation) that support forming (e.g., along each trench 405, in sets along the z-direction) the set of piers 505 (e.g., dielectric piers). For example, the third set of operations may include depositing a material 510 in the cavities (e.g., in contact with exposed sidewalls of the stack of layers 310, in contact with the substrate 305) to form the piers 505. In some examples, the material 510 may be a dielectric material or an oxide material. In some examples, the material 510 of the piers 505 may be chosen for having relatively high strength, high stiffness, bonding strength with the material 315, bonding strength with the substrate 305, or any combination thereof. In some examples, the material 510 of the piers 505 may be chosen for having a high selectivity for differential processing relative to the material 320, such as examples where the material 320 is removed in subsequent operations. In some examples, the piers 505 may be formed from multiple materials 510 deposited in the cavities, such as when a pier 505 is formed by first depositing a liner material (e.g., a dielectric liner) in the cavities, followed by filling the liner material (e.g., with a material that may be a conductor, a semiconductor, or a dielectric). In some examples, the third set of operations may include planarization operation (e.g., a polishing operation, a CMP operation) to flatten a top surface of the material arrangement 300-c, which may support aspects of subsequent operations.

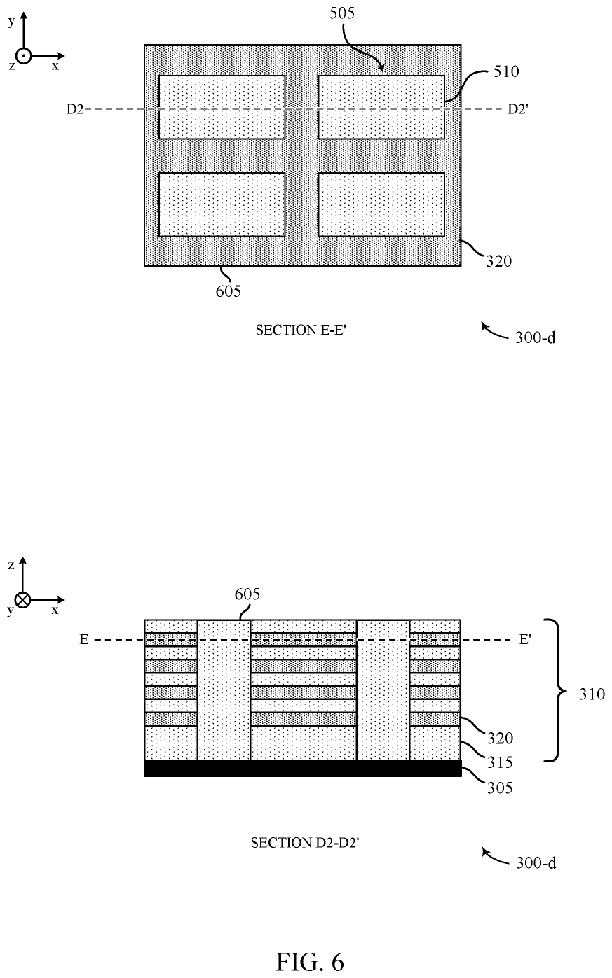

FIG. 6 illustrates an example of a material arrangement 300 (e.g., as a material arrangement 300-d) after a second alternative including a second set of one or more manufacturing operations that support lateral split digit line memory architectures in accordance with examples as disclosed herein. These second set of manufacturing operations included in the second alternative may be performed on the material arrangement 300-a to form the material arrangement 300-d (e.g., as an alternative to the second set of manufacturing operations performed on the material arrangement 300-a to form the material arrangement 300-b). In some examples, the alternative second set of operations may include forming a set of piers 505. As discussed above, a pier 505 may be an example of a support structure, such as a pillar or column of dielectric material which adheres to or supports the stack of layers 310, the substrate 305, the conductive contacts 325, or a combination thereof. In some examples, the piers 505 may provide mechanical support to the stack of material during subsequent steps of the manufacturing process. For example, a pier 505 may limit movement of the stack of materials in the x-direction, the y-direction, the z-direction, or any combination thereof.

To form the piers 505 illustrated in the material arrangement 300-d, a set of cavities may be formed by performing a vertical etch through the stack of materials using a first etching mask. In some cases, the etching may terminate above the substrate 305 and the conductive contacts 325. That is, the substrate 305 and the conductive contacts 325 may not be etched during the etching process. In some cases, the substrate 305 may be exposed by the forming of the cavities. Then, the alternative second set of operations may include depositing a pier material 510, such as a dielectric material, into each of the set of cavities. The dielectric material 510 may fill the set of cavities, and may contact each layer of the stack of layers 310 (e.g., each layer of the material 315, each layer of the material 320). Additionally, or alternatively, a pier 505 may include a dielectric liner material, such as an oxide or a nitride, and a filler material, such as an aluminum oxide (AlOx), an oxide, or polysilicon.

Accordingly, the set of piers 505 may provide mechanical support for the stack of layers 310 during subsequent steps of the manufacturing process. In some examples, the dielectric material 510 of the piers 505 may be the same as the dielectric material of the material 315. Alternatively, the material 510 of the piers 505 may be examples of different materials or combinations of materials (e.g., relative to the material 315). In some examples, forming the set of piers 505 may include a polishing step. For instance, after depositing the pier material 510, the stack of layers 310 may be polished or planarized, for example using a CMP procedure.

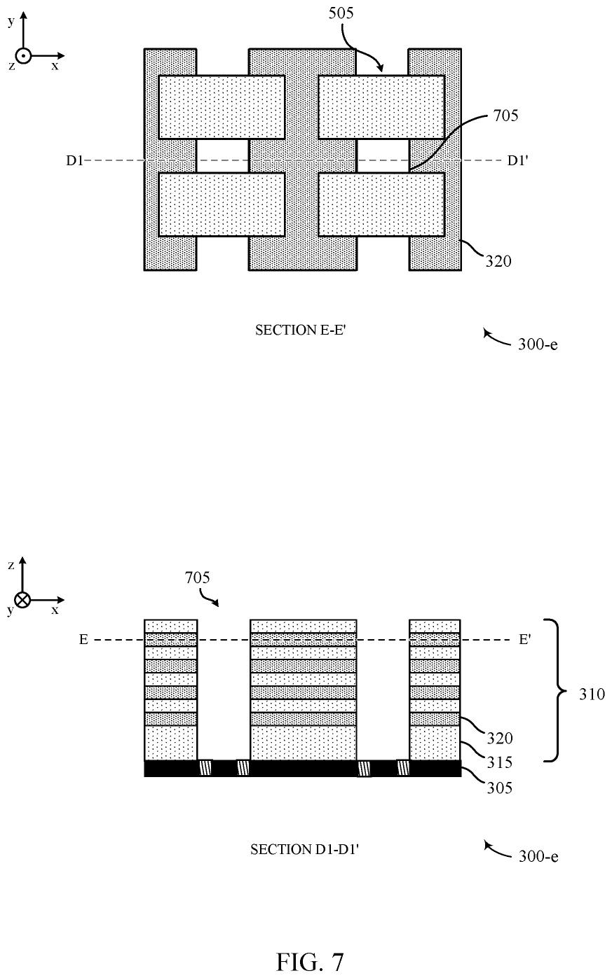

FIG. 7 illustrates an example of a material arrangement 300 (e.g., as a material

arrangement 300-c) after a third set of one or more manufacturing operations included in the second alternative that support lateral split digit line memory architectures in accordance with examples as disclosed herein. These third set of manufacturing operations may be performed on the material arrangement 300-d to form the material arrangement 300-e (e.g., as an alternative to the third set of manufacturing operations performed on the material arrangement 300-b to form the material arrangement 300-c). The alternative third set of operations may include forming a set of cavities 705 in the material arrangement 300-c. The set of cavities 705 may be formed by etching or removing material from the stack of layers 310 (e.g., the layers of the material 315, the layers of the material 320). In some cases, forming the set of cavities 705 may expose a portion of sidewalls of the piers 505, as well exposing portions of the stack of layers 310. Additionally, forming the set of cavities 705 may expose portions of the substrate 305 and conductive contacts 325. For example, forming each cavity 705 may expose a respective first sidewall of the stack of layers 310 on a first side of the cavity 705 (e.g., along the x-direction) and a respective second sidewall of the stack of layers 310 on a second side of the cavity 705 (e.g., along the x-direction). In some examples, forming each cavity 705 may expose a respective sidewall of a first pier 505 (e.g., of material 510) on a first side of the cavity 705 (e.g., along the y-direction) and a respective sidewall of a second pier 505 on a second side of the cavity 705 (e.g., along the y-direction).

In some examples, the etching process to form the set of cavities 705 may be selective to the material of the set of piers 505 and the stack of layers 310. That is, the etching process may selectively remove material, such as the material 315 and the material 320, while preserving the material of the set of piers 505 or the stack of layers 310. Accordingly, the pattern used to etch the set of cavities 705 may etching a set of isolated holes (e.g., corresponding to the location of each of the cavities 705). In such cases, the etching process may be directional (e.g., etching along the z direction).

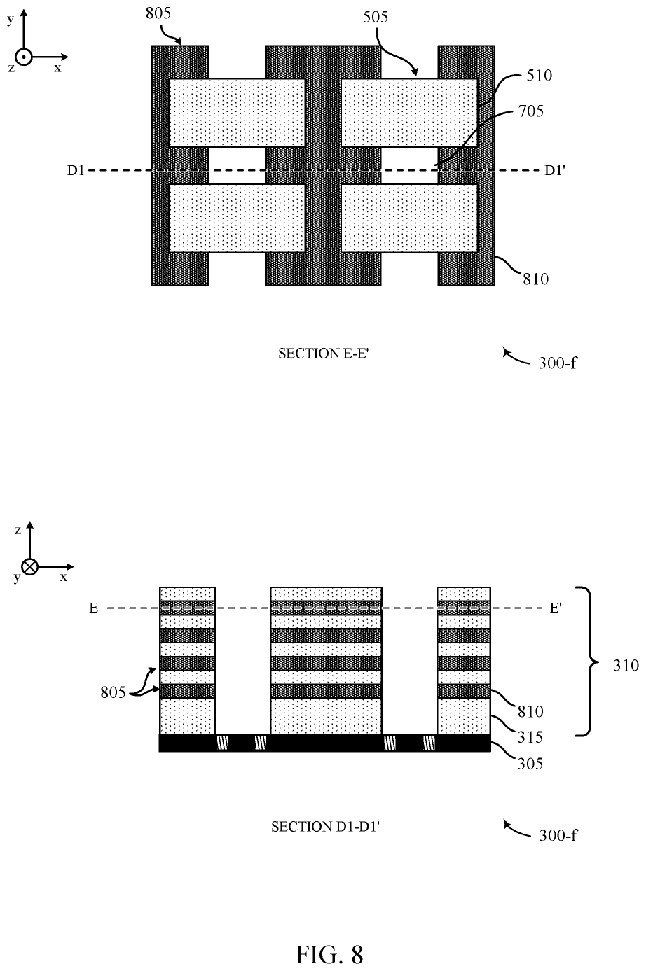

FIG. 8 illustrates an example of a material arrangement 300 (e.g., as a material arrangement 300-f) after a fourth set of one or more manufacturing operations that support lateral split digit line memory architectures in accordance with examples as disclosed herein. The fourth set of operation may include operations (e.g., a pillar etch operation) that support forming a set of access lines 805. There may be two alternative sets of fourth operations to form the material arrangement 300-f: a first alternative of the fourth set of operations performed on the material arrangement 300-c to form the material arrangement 300-f and a second alternative of the fourth set of operations performed on the material arrangement 300-e to form the material arrangement 300-f.

In the first alternative of the fourth set of operations (e.g., where a trench and pier method of manufacturing is used to form the material arrangement 300-c), the fourth set of operations may include operations that support forming the cavities 705 based on removing portions of the material 410 (e.g., along the z-direction, to the substrate 305, to the conductive contacts 325, or to an intervening material between the stack of layers 310 and the substrate 305, following the operations of FIG. 5). In some examples, forming each cavity 705 may expose a respective first sidewall of the stack of layers 310 on a first side of the cavity 705 (e.g., along the x-direction) and a respective second sidewall of the stack of layers 310 on a second side of the cavity 705 (e.g., along the x-direction). In some examples, forming each cavity 705 may expose a respective sidewall of a first pier 505 (e.g., of material 510) on a first side of the cavity 705 (e.g., along the y-direction) and a respective sidewall of a second pier 505 on a second side of the cavity 705 (e.g., along the y-direction). In some examples, forming the cavities 705 may involve depositing and patterning a masking material (e.g., above the material arrangement 300-c including the stack of layers 310, the material 510, and the material 410, not shown), which may be followed by an etching operation (e.g., a dry etching operation, such as RIE, that supports material removal that is preferentially directional along the z-direction). In some other examples, forming the cavities 705 may omit patterning and may, alternatively, employ another material removal operation, such as a wet etch operation, that preferentially removes remaining portions of the material 410. In some examples, (e.g., when the material 410 is the same as the material 320), such an etching operation may also be associated with removing remaining portions of the material 320. In some cases, performing operations on the material arrangement 300-c to form the cavities 705 may form a material stack that is similar to the material arrangement 300-e illustrated in FIG. 7.

Then, in both the first and the second alternatives, operations are performed (e.g., on a material arrangement that is or that is similar to the material arrangement 300-e) to replace the layers of the nitride material 320 in the stack of layers 310 with layers of a conductive material 810. For example, the fourth set of operations may include operations (e.g., exhumation operations, nitride exhumation) that support forming voids between the layers of material 315. For example, the fourth set of operations may include removing (e.g., etching, exhuming) the material 320, which may form the voids between the remaining layers of the material 315. The fourth set of operations also may expose sidewalls, or portions thereof, of the piers 505 (e.g., of the material 510, sidewalls in an xz-plane, sidewall portions in a yz-plane between layers of the material 315). In the example of the first alternative, a single wet etch operation may be performed to remove both the material 410 (e.g., from the trench 405) and the layers of material 320 from the stack of layers 310.

The piers 505 may remain in contact with the layers of the material 315 and the substrate 305, which may provide mechanical support to the remaining portions of the material 315 (e.g., reducing deflection of the remaining layers of the material 315 along the z-direction, reducing deflection of the remaining layers of the material 315 along the x-direction, reducing bending of the remaining layers of the material 315, reducing an unsupported length or cantilever of the remaining layers of the material 315). Thus, by implementing the piers 505 of material 510, the cavities 705 and the voids may be formed with improved stability or tolerances, such that formation of features within the cavities 705 and the voids (e.g., pillars, word lines, memory cells, between the remaining layers of the material 315 along the z-direction) may be performed with reduced variability or otherwise improved consistency.

The fourth set of operations may also include operations (e.g., one or more conductor deposition operations) that support forming the access lines 805 (e.g., word lines) based on depositing materials 810 (e.g., conductive materials) in the voids. In some examples, the fourth set of operations may include depositing a first conductive material 810 on exposed surfaces of the material arrangement 300, which may include depositing the first conductive material 810 in contact with the layers of the material 315, in contact with the substrate 305, and in contact with exposed sidewalls, or portions thereof, of the piers 505.

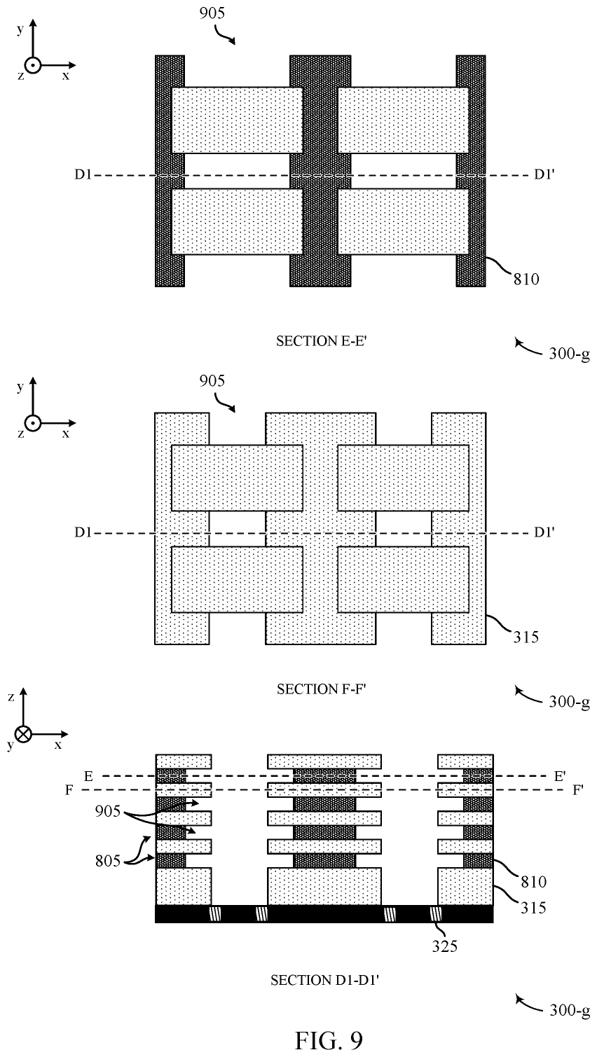

FIG. 9 illustrates an example of a material arrangement 300 (e.g., as a material arrangement 300-g) after a fifth set of one or more manufacturing operations that support lateral split digit line memory architectures in accordance with examples as disclosed herein. The fifth set of manufacturing operations may be performed on the material arrangement 300-f to form the material arrangement 300-g. The fifth set of operations may include further operations (e.g., a metal recess etch) that support forming voids 905 between the layers of the material 315. For example, the fifth set of operations may include removing (e.g., etching) exposed portions of the one or more materials 810, which may recess portions of the materials 810 to form the voids 905. The top and bottom surfaces of the voids 905 may each be defined by different layers of the material 315, and a sidewall of the voids 905 may be each be defined by the material 810 (e.g., that forms the access lines 805).

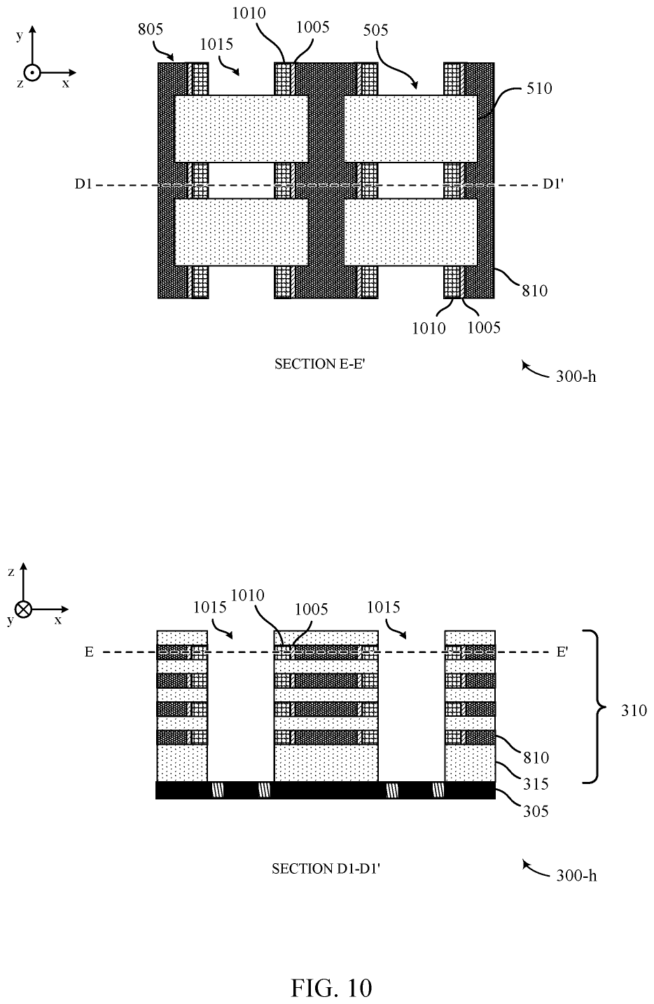

FIG. 10 illustrates an example of a material arrangement 300 (e.g., as a material arrangement 300-h) after a sixth set of one or more manufacturing operations that support lateral split digit line memory architectures in accordance with examples as disclosed herein. The sixth set of operations may include operations that support forming electrodes coupled with the access lines 805. For example, the sixth set of operations may include depositing conductive material 1005 within the set of voids 905 to contact the conductive material 810 (e.g., that forms the access lines 805). In some cases, the sixth set of operations may additionally involve a subsequent recess operation to recess the material 1005 to form a set of be within the voids 905. For example, a lateral etching process may be performed to etch portions of the material 1005 to form another set of voids between the layers of the material 315 that are each smaller than the voids 905 (e.g., based on depositing the material 1005 in the voids 905). In some examples, the sixth set of operations may also include depositing a material 1010 (e.g., dielectric material) in contact with exposed portions of the material 1005, which also may involve a subsequent recess operation to recess the material 1010 to be within the voids 905. In some instances, the sixth set of operations may additionally involve a subsequent recess operation to recess the material 1010 to be within the voids 905 (e.g., rather than extending beyond the voids 905 to, for example, be contacting sidewalls of the material 315).

After depositing the material 1010, the material arrangement 300-h may include a set of cavities 1015 that extend through the stack of layers 310 and expose the substrate 305. Sidewalls of the cavities 1015 may each include alternating layers of the material 1010 and the material 315 and sidewalls of the piers 505.

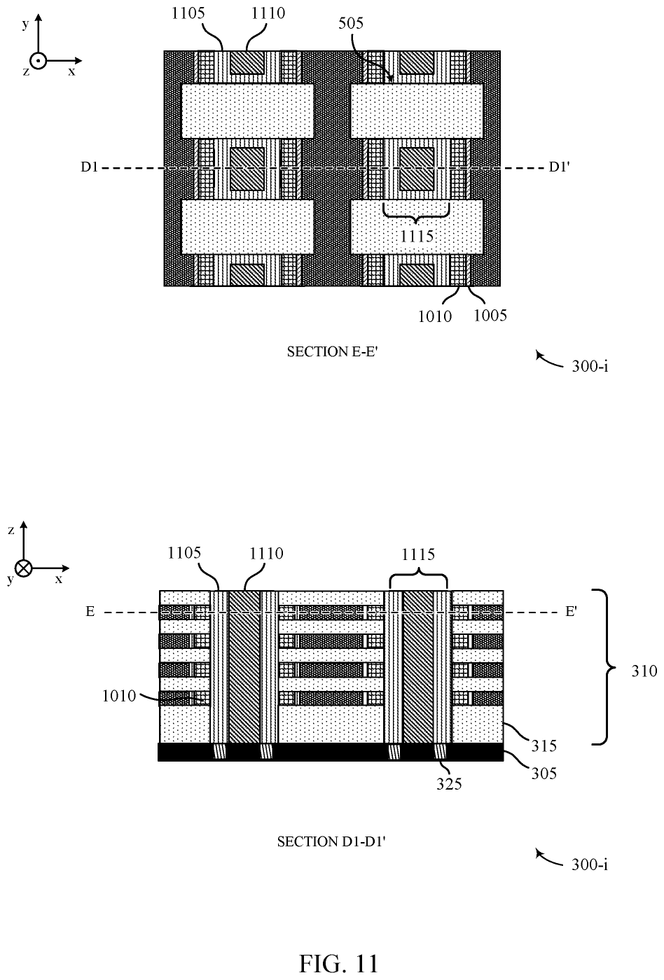

FIG. 11 illustrates an example of a material arrangement 300 (e.g., as a material arrangement 300-i) after a seventh set of one or more manufacturing operations that support lateral split digit line memory architectures in accordance with examples as disclosed herein. The seventh set of operations may include operations that support forming dielectric pillars 1115 in the cavities 1015. In some examples, the seventh set of operations may include conformally depositing a material 1105 (e.g., a doped polysilicon material, an aluminum oxide material) in the cavities 1015 to form a sheath. After conformally depositing the material 1105, a layer of the material 1105 that is substantially a same thickness may contact the sidewalls of the layers of the material 315, the sidewalls of the material 1010, the substrate 305, and sidewalls of the piers 505. In various examples, the material 1105 may be a dielectric material associated with a different selectivity to other materials already in the material arrangement 300 (e.g., such as a metal, a carbide, a titanium nitride, titanium silicon nitride, tungsten silicon nitride). In some cases, conformally depositing the material 1105 may form a second set of cavities that are smaller than the cavities 1015.

The seventh set of operations may also include depositing a material 1110 (e.g., a dielectric material) in the second set of smaller cavities to contact exposed surfaces of the material 1105 (e.g., and the substrate 305, and the conductive contacts 325). As such, the material 1110 may be surrounded by and in contact with the material 1105 (e.g., in the xy-plane). In some examples, the material 1110 may include a dielectric material, such as aluminum oxide.

Accordingly, the material arrangement 300-i may include a set of dielectric pillars 1115 formed at least in part from the material 1105 and the material 1110, and may, in various examples, be in contact with the material 1010. Each of the dielectric pillars 1115 may extend through the stack of layers 310 to contact one or more contacts 325, where each of the contacts may be coupled with a single dielectric pillar 1115 and may be associated with a single digit line. Sidewalls of the dielectric pillars 1115 may contact alternating layers of the materials 315 and alternating layers of the material 1010 and sidewalls of the piers 505.

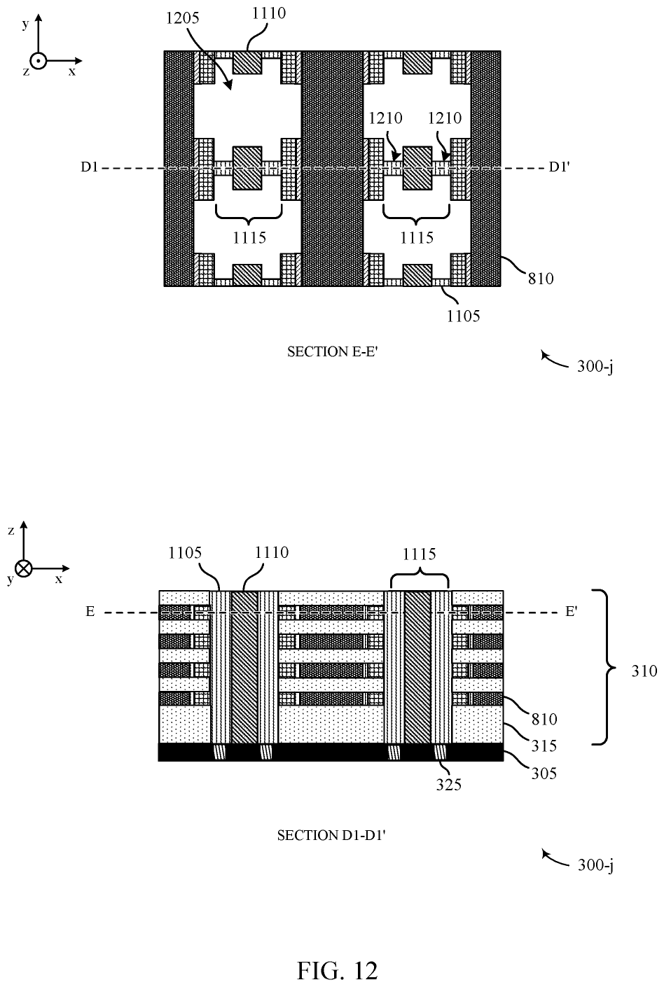

FIG. 12 illustrates an example of a material arrangement 300 (e.g., as a material arrangement 300-j) after an eighth set of one or more manufacturing operations that support lateral split digit line memory architectures in accordance with examples as disclosed herein. The eighth set of operations may include operations (e.g., an etch operation) that support forming cavities 1205 based on removing portions of the material 510 (e.g., the piers 505) and the material 1105 (e.g., along the z-direction, to the substrate 305, to the conductive contacts 325, or to an intervening material between the stack of layers 310 and the conductive contacts 325). For example, the eighth set of operations may include removing a first portion of the material 1105 and a second portion of the material 1105 from each dielectric pillar 1115. After the eighth set of operations, each dielectric pillar 1115 may include two remaining portions 1210 of the dielectric material 1105. Each remaining portion 1210 of the dielectric material 1105 may couple the dielectric pillar 1115 with one of the sidewalls of the stack of layers 310. In some cases, the remaining portions 1210 of the dielectric material 1105 may increase a stability of the dielectric pillars 1115 in the material arrangement 300-j (e.g., as compared to a similar material arrangement 300-j where the dielectric pillars 1115 are not coupled with sidewalls of the stack of layers 310 via remaining portions 1210 of the dielectric material 1105). Such etching may create cavities in which conductive pillars (e.g., digit lines) may be formed.

In some examples, forming each cavity 1205 may expose a respective first sidewall of the stack of layers 310 on a first side of the cavity 1205 (e.g., along the x-direction) and a respective second sidewall of the stack of layers 310 on a second side of the cavity 1205 (e.g., along the x-direction). Additionally, forming each cavity 1205 may expose sidewalls of the material 1005, the material 1010, the material 1105, and the material 1110 within each cavity 1205, such that a first quantity of the material 1005, the material 1010, the material 1105, and the material 1110, and a second quantity of the material 1005, the material 1010, the material 1105, and the material 1110 may be included in each of the cavities 1205.

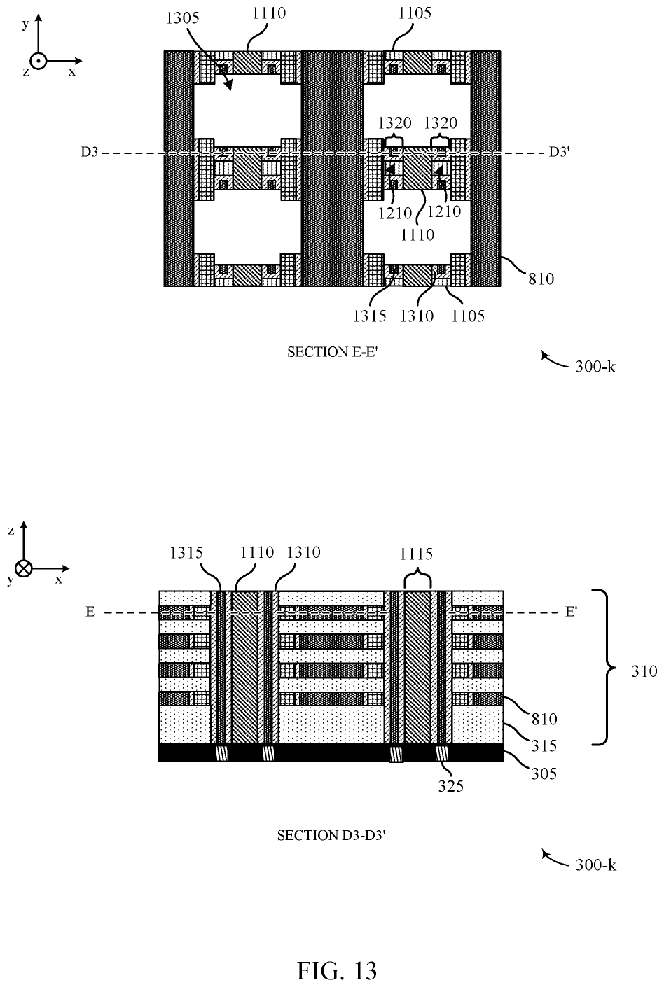

FIG. 13 illustrates an example of a material arrangement 300 (e.g., as a material arrangement 300-k) after a ninth set of one or more manufacturing operations that support lateral split digit line memory architectures in accordance with examples as disclosed herein. The ninth set of operations may include operations that support forming conductive pillars 1320 (e.g., configured as digit lines) based on depositing a conductive materials 1310 (e.g., electrode material, bottom electrodes) and 1315 in the cavities 1205. For example, the ninth set of operations may include conformally depositing the material 1310 to line exposed surfaces of the cavities 1205. Then, the ninth set of operations may include depositing the material 1315 (e.g., another conductive material 1315) into remaining portions of the cavities 1205. After these deposition operations, the material arrangement 300-k may not include cavities 1305. For example, sidewalls of the cavities 1305 may be conformally lined with the material 1310 and a remainder of the cavities 1305 may be filled with the material 1315. The conductive materials 1310 and 1315 (e.g., electrode material, bottom electrodes) may be an example of conductive pillars that act as digit lines.

To form the material arrangement 300-k, the ninth set of operations may include operations (e.g., exhumation operations, nitride exhumation) that support forming the cavities 1305. For example, the ninth set of operations may include performing a dry etching process to remove portions of the material 1315 from the material arrangement 300-k. After the dry etching process, the material arrangement 300-k may include portions of the material 1315 within the conductive pillars 1320. The ninth set of operations may additionally include a selective wet etching process to selectively remove portions of the material 1310 from sidewalls of the material arrangement 300 to form the cavities 1305. In some cases, the portions of the material 1310 within the conductive pillars 1320 may remain in the material arrangement 300-k because the selective wet etching process may not remove portions of the material 1310 that are surrounding the material 1315. Thus, after the selective wet etching process, the material arrangement 300-k may include a set of conductive pillars 1320 that each contact sidewalls of a remaining portion 1210 of the material 1105 and sidewalls of a dielectric pillar 1115.

In some cases, the remaining portions 1210 of the material 1105 (e.g., the pillar sheath) may allow the formation of the “divided” digit lines as described herein, while also avoiding challenges that may occur when other processes that may not include a pillar sheath. As such, the digit lines formed by conductive pillars 1320 may have a same or higher density as digit lines and pillars that do not use lateral split digit line processes (e.g., architectures with two digit lines to each pillar).

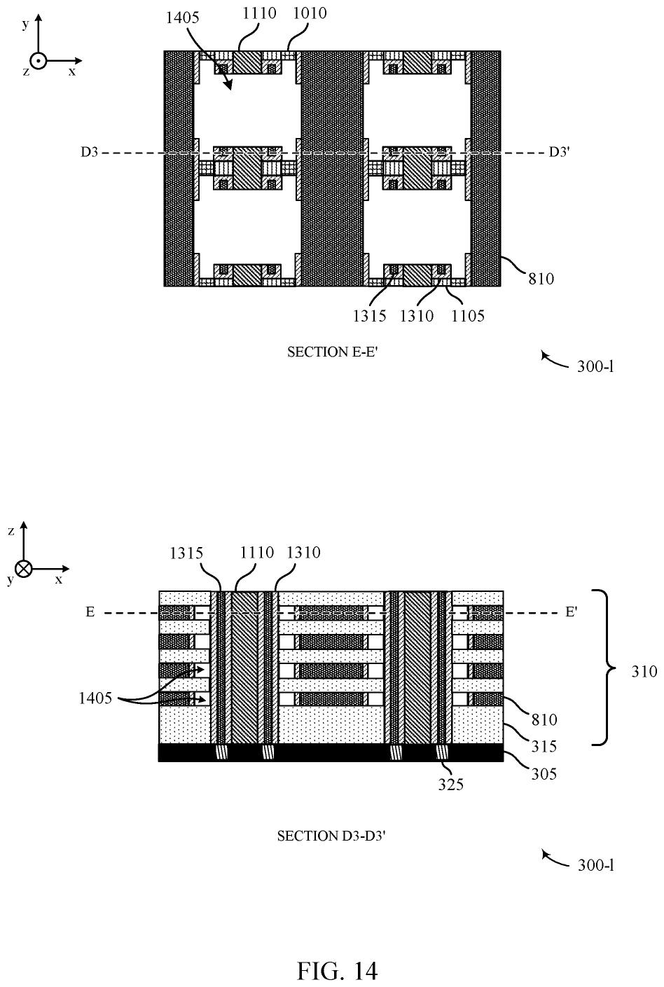

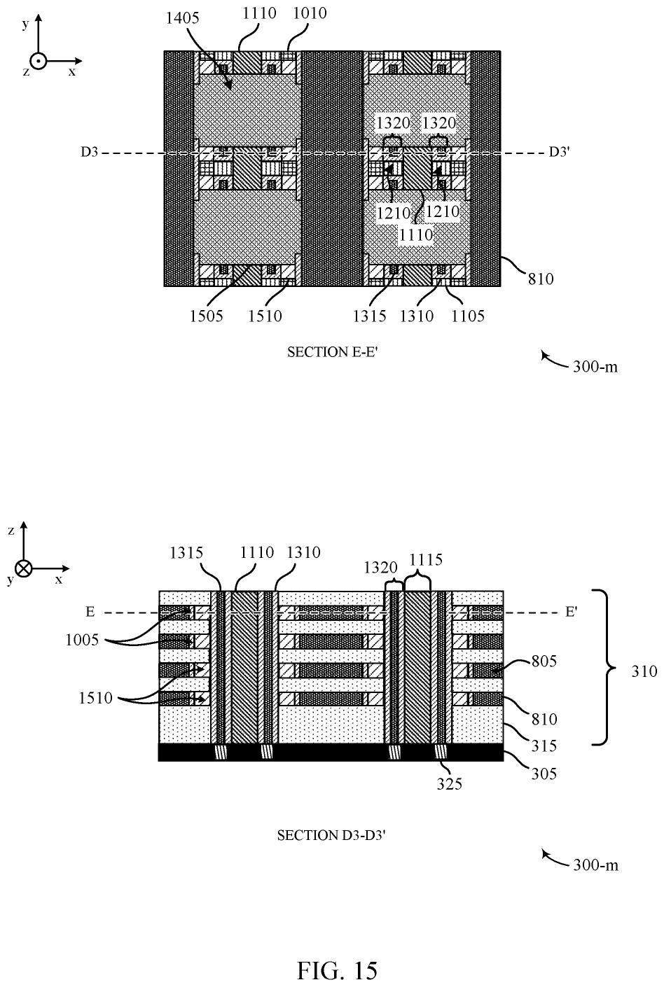

FIG. 14 illustrates an example of a material arrangement 300 (e.g., as a material arrangement 300-l) after a tenth set of one or more manufacturing operations that support lateral split digit line memory architectures in accordance with examples as disclosed herein. The tenth set of operations may include operations (e.g., an etch operation) that support forming voids 1405 based on removing portions of the material 1010 (e.g., along the z-direction, to an adjacent layer of the material 315, between layers of the material 315). In some examples, forming each void 1405 may expose a respective first sidewall of the stack of layers 310 on a first side of the void 1405 (e.g., along the x-direction) and a respective second sidewall of the stack of layers 310 on a second side of the void 1405 (e.g., along the x-direction). In some examples, exposing sidewalls of the stack of layers 310 may include exposing a single layer of the material 810 (e.g., such that the voids 1405 may not expose the substrate 305, that layers of the material 315 may remain above and below the voids 1405). Additionally, forming each void 1405 may expose sidewalls of the material 1310, remaining portions of the material 1010, and the material 1005 within each void 1405. The cavities formed adjacent to the materials 1310 and 1315 may be configured to receive a memory material 1510, as described with reference to FIG. 15.

FIG. 15 illustrates an example of a material arrangement 300 (e.g., as a material arrangement 300-m) after an eleventh set of one or more manufacturing operations that support lateral split digit line memory architectures in accordance with examples as disclosed herein. The eleventh set of operations may include operations that support forming memory cells, electrically coupled with the access lines 805 (e.g., coupled with the materials 810 along the x-direction) based on depositing a memory material 1510 in portions of the voids 1405. For example, the eleventh set of operations may include depositing the material 1510 (e.g., a memory material, a storage material, a chalcogenide) in voids defined by adjacent layers of the material 1005, the material 1010, and the material 1310 (e.g., sidewalls of the digit lines). The eleventh set of operations may also involve a subsequent recess operation to recess that material 1510 to be within voids. In some examples, the eleventh set of operations may also include depositing a sealing layer, or by applying a plasma treatment, such as with ammonia (NH₃) to the material 1510.

The eleventh set of operations may include depositing a material 1505 (e.g., a dielectric material) in the remaining portions of the voids 1405. For example, after forming the memory cells in the voids defined by adjacent layers of the material 315, the material 1005, the material 1010, and the material 1310 (e.g., sidewalls of the digit lines), the material 1505 may be deposited into the voids 1405 and may contact the substrate 305.

Accordingly, the described techniques for lateral split digit line memory architectures may support various examples for forming an apparatus including aspects of a memory array. For example, a memory array may include the material arrangement 300-m, where the conductive pillars 1320 (e.g., including the conductive materials 1310 and 1315) are configured as digit lines, the layers of the conductive material 810 are configured as access lines 805 (e.g., word line plates), the material 1310 and 1005 are configured as electrodes, and each portion of the material 1510 is configured as a memory cell. In this example, each memory cell may be in contact with adjacent layers of the material 315 (e.g., a dielectric material), the material 1505 (e.g., another dielectric material), a portion of the material 1005 (e.g., a conductive material that forms an electrode), and the material 1310 (e.g., another conductive material that forms another electrode). Thus, each storage element may be electrically coupled with a word line plate (e.g., via the electrode including the material 1005) and a digit line (e.g., via the electrode including the material 1105).

In the example of a memory array that includes the material arrangement 300-m, the memory array may include a set of dielectric pillars 1115 (e.g., formed of the material 1110 and remaining portions 1210 of the material 1105) that extend through the stack of layers 310 and contact the substrate 305. In some cases, there may be four conductive pillars 1320 (e.g., each configured as one digit line) that are isolated from one another by a single dielectric pillar 1115. Each of the conductive pillars 1320 may correspond to a single digit line and may extend through the stack of layers 310 and be in contact with a contact 325. The dielectric material 1505 may also extend between the dielectric pillars 1115 and associated conductive pillars 1320 to electrically isolate each of the conductive pillars 1320 that contact a first dielectric pillar 1115 with the conductive pillars 1320 that contact a second dielectric pillar 1115. Further, in each layer of the stack of layers 310, each of the dielectric pillars 1115 may contact four memory cells (e.g., including the material 1510). In some cases, each of the four memory cells (e.g., associated with one of the dielectric pillars 1115) may be coupled with a word line plate that is associated with a first word line driver. In some other examples, there may be two conductive pillars 1320 that are isolated from one another by a single dielectric pillar 1115. In the case of two conductive pillars 1320, each of the two conductive pillars 1320 (e.g., and any associated memory cells) may be coupled with an even word line plate and an odd word line plate which are separated from each other and associated with word line drivers.

FIG. 16 illustrates a flowchart showing a method 1600 that supports lateral split digit line memory architectures in accordance with examples as disclosed herein. The operations of method 1600 may be implemented by a manufacturing system or its components as described herein. For example, the operations of method 1600 may be performed by a manufacturing system as described with reference to FIGS. 1 through 15. In some examples, a manufacturing system may execute a set of instructions to control the functional elements of the device to perform the described functions. Additionally, or alternatively, the manufacturing system may perform aspects of the described functions using special-purpose hardware.

At 1605, the method may include forming, through a stack of layers over a substrate, a trench to expose the substrate, the stack of layers including layers of a first dielectric material and a nitride material. The operations of 1605 may be performed in accordance with examples as disclosed herein.

At 1610, the method may include forming, along the trench, a plurality of dielectric piers each including a second dielectric material based at least in part on depositing respective second dielectric material portions in the trench. The operations of 1610 may be performed in accordance with examples as disclosed herein.

At 1615, the method may include forming a plurality of access lines based at least in part on removing the nitride material from the stack of layers and depositing a first conductive material in a plurality of voids between the layers of the first dielectric material. The operations of 1615 may be performed in accordance with examples as disclosed herein.

At 1620, the method may include forming, along the trench, a plurality of dielectric pillars each including a third dielectric material that surrounds a fourth dielectric material based at least in part on depositing the third dielectric material and the fourth dielectric material in a plurality of first cavities disposed between each of the plurality of dielectric piers. The operations of 1620 may be performed in accordance with examples as disclosed herein.

At 1625, the method may include removing the plurality of dielectric piers, a first portion of the third dielectric material, and a second portion of the third dielectric material opposite the first portion to form a third portion of the third dielectric material and a fourth portion of the third dielectric material positioned opposite the third portion, where the third portion of the third dielectric material, the fourth portion of the third dielectric material, and the fourth dielectric material form a plurality of second cavities that expose the substrate. The operations of 1625 may be performed in accordance with examples as disclosed herein.

At 1630, the method may include forming a plurality of conductive pillars along the trench by depositing a second conductive material into the plurality of second cavities, each of the plurality of conductive pillars contacting sidewalls of the third dielectric material and the fourth dielectric material. The operations of 1630 may be performed in accordance with examples as disclosed herein.

At 1635, the method may include forming, after forming the plurality of conductive pillars, a plurality of memory cells based at least in part on depositing a memory material, each of the plurality of memory cells electrically coupled with one conductive pillar of the plurality of conductive pillars and one of the plurality of access lines. The operations of 1635 may be performed in accordance with examples as disclosed herein.

In some examples, an apparatus as described herein may perform a method or methods, such as the method 1600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming, through a stack of layers over a substrate, a trench to expose the substrate, the stack of layers including layers of a first dielectric material and a nitride material; forming, along the trench, a plurality of dielectric piers each including a second dielectric material based at least in part on depositing respective second dielectric material portions in the trench; forming a plurality of access lines based at least in part on removing the nitride material from the stack of layers and depositing a first conductive material in a plurality of voids between the layers of the first dielectric material; forming, along the trench, a plurality of dielectric pillars each including a third dielectric material that surrounds a fourth dielectric material based at least in part on depositing the third dielectric material and the fourth dielectric material in a plurality of first cavities disposed between each of the plurality of dielectric piers; removing the plurality of dielectric piers, a first portion of the third dielectric material, and a second portion of the third dielectric material opposite the first portion to form a third portion of the third dielectric material and a fourth portion of the third dielectric material positioned opposite the third portion, where the third portion of the third dielectric material, the fourth portion of the third dielectric material, and the fourth dielectric material form a plurality of second cavities that expose the substrate; forming a plurality of conductive pillars along the trench by depositing a second conductive material into the plurality of second cavities, each of the plurality of conductive pillars contacting sidewalls of the third dielectric material and the fourth dielectric material; and forming, after forming the plurality of conductive pillars, a plurality of memory cells based at least in part on depositing a memory material, each of the plurality of memory cells electrically coupled with one conductive pillar of the plurality of conductive pillars and one of the plurality of access lines.

Aspect 2: The method, apparatus, or non-transitory computer-readable medium of aspect 1, where the third portion of the third dielectric material and the fourth portion of the third dielectric material mechanically couple the fourth dielectric material with sidewalls of the trench after forming the plurality of second cavities.

Aspect 3: The method, apparatus, or non-transitory computer-readable medium of any of aspects 1 through 2, where forming the plurality of dielectric pillars further includes operations, features, circuitry, logic, means, or instructions, or any combination thereof for conformally depositing the third dielectric material on sidewalls of the plurality of first cavities to form a plurality of third cavities that are each smaller than the plurality of first cavities and depositing the fourth dielectric material in the plurality of third cavities.

Aspect 4: The method, apparatus, or non-transitory computer-readable medium of any of aspects 1 through 3, where forming the plurality of conductive pillars further includes operations, features, circuitry, logic, means, or instructions, or any combination thereof for forming the plurality of conductive pillars including a first conductive pillar and a second conductive pillar that are electrically coupled with a first digit line driver and a third conductive pillar and a fourth conductive pillar that are electrically coupled with a second digit line driver.

Aspect 5: The method, apparatus, or non-transitory computer-readable medium of any of aspects 1 through 4, where forming the plurality of conductive pillars further includes operations, features, circuitry, logic, means, or instructions, or any combination thereof for conformally depositing a third conductive material into the plurality of second cavities; depositing the second conductive material into the plurality of second cavities after conformally depositing the third conductive material; performing a dry etching process to remove portions of the second conductive material; and performing a selective wet etching process to selectively remove portions of the third conductive material from sidewalls of the plurality of second cavities, where each conductive material includes remaining portions of the third conductive material at least partially surrounding the remaining portions of the second conductive material.

Aspect 6: The method, apparatus, or non-transitory computer-readable medium of any of aspects 1 through 5, where forming the plurality of second cavities further includes operations, features, circuitry, logic, means, or instructions, or any combination thereof for performing a first exhumation process to remove the plurality of dielectric piers and performing, after performing the first exhumation process, a second exhumation process to remove the first portion of the third dielectric material and the second portion of the third dielectric material.

Aspect 7: The method, apparatus, or non-transitory computer-readable medium of any of aspects 1 through 6, further including operations, features, circuitry, logic, means, or instructions, or any combination thereof for forming the plurality of voids between the layers of the first dielectric material based at least in part on removing the layers of the nitride material and removing a second nitride material from the trench after forming the plurality of dielectric piers; depositing the first conductive material into the plurality of voids between the layers of the first dielectric material to form alternating layers of the first dielectric material and the first conductive material; and forming a plurality of second voids between the layers of the first dielectric material based at least in part on removing portions of the first conductive material from each layer of the first conductive material, where each of the plurality of second voids are defined by different layers of the first dielectric material and a sidewall of the first conductive material, and where the plurality of access lines include the first conductive material and are formed based at least in part on forming the plurality of second voids.

Aspect 8: The method, apparatus, or non-transitory computer-readable medium of aspect 7, further including operations, features, circuitry, logic, means, or instructions, or any combination thereof for depositing a fourth conductive material in each of the plurality of second voids, the fourth conductive material in contact with the plurality of access lines; performing a lateral etching process to etch portions of the fourth conductive material to form a plurality of third voids between the layers of the first dielectric material; and depositing a fifth dielectric material in each of the plurality of third voids, the fifth dielectric material electrically coupled with the plurality of access lines via the fourth conductive material, where forming the plurality of conductive pillars occurs after depositing the fifth dielectric material.

Aspect 9: The method, apparatus, or non-transitory computer-readable medium of aspect 8, further including operations, features, circuitry, logic, means, or instructions, or any combination thereof for performing, after forming the plurality of conductive pillars, a second lateral etching process to etch portions of the fifth dielectric material to form a plurality of fourth voids between the layers of the first dielectric material, where each of the plurality of fourth voids are defined by different layers of the first dielectric material, a sidewall of the fifth dielectric material, and a sidewall of one conductive pillar of the plurality of conductive pillars.

Aspect 10: The method, apparatus, or non-transitory computer-readable medium of aspect 9, where forming the plurality of memory cells further includes operations, features, circuitry, logic, means, or instructions, or any combination thereof for depositing the memory material into the plurality of fourth voids.

Aspect 11: The method, apparatus, or non-transitory computer-readable medium of any of aspects 7 through 10, where forming the plurality of voids further includes operations, features, circuitry, logic, means, or instructions, or any combination thereof for performing a wet etching process to selectively remove the nitride material and the second nitride material.

Aspect 12: The method, apparatus, or non-transitory computer-readable medium of any of aspects 1 through 11, further including operations, features, circuitry, logic, means, or instructions, or any combination thereof for depositing, after forming the plurality of memory cells, a sixth dielectric material into a plurality of fourth cavities, where the plurality of fourth cavities each extend between two of the plurality of dielectric pillars and are formed based at least in part on depositing the second conductive material into the plurality of second cavities.

Aspect 13: The method, apparatus, or non-transitory computer-readable medium of any of aspects 1 through 12, where forming the trench divides each layer of the nitride material into a first portion associated with a first word line driver and a second portion associated with a second word line driver; forming the plurality of access lines further includes; forming a plurality of first access lines electrically coupled with the first word line driver based at least in part on depositing the first conductive material in voids associated with the first portion of the nitride material; and forming a plurality of second access lines electrically coupled with the second word line driver based at least in part on depositing the first conductive material in voids associated with the second portion of the nitride material.

Aspect 14: The method, apparatus, or non-transitory computer-readable medium of any of aspects 1 through 13, where sidewalls of the plurality of first cavities include alternating layers of the first dielectric material and a fifth dielectric material.

Aspect 15: The method, apparatus, or non-transitory computer-readable medium of any of aspects 1 through 14, further including operations, features, circuitry, logic, means, or instructions, or any combination thereof for depositing a second nitride material into the trench and forming a plurality of fifth cavities each extending through the second nitride material, portions of the first dielectric material, and portions of the nitride material to expose the substrate, where forming the plurality of dielectric piers includes depositing the respective second dielectric material portions into the plurality of fifth cavities.

Aspect 16: The method, apparatus, or non-transitory computer-readable medium of aspect 15, where forming each fifth cavity of the plurality of fifth cavities exposes a respective first sidewall of the stack of layers on a first side of each fifth cavity and a respective second sidewall of the stack of layers on a second side of each fifth cavity and forming the plurality of dielectric piers includes depositing, in each fifth cavity, the respective second dielectric material portion in contact with the respective first sidewall and the respective second sidewall.

FIG. 17 illustrates a flowchart showing a method 1700 that supports lateral split digit line memory architectures in accordance with examples as disclosed herein. The operations of method 1700 may be implemented by a manufacturing system or its components as described herein. For example, the operations of method 1700 may be performed by a manufacturing system as described with reference to FIGS. 1 through 15. In some examples, a manufacturing system may execute a set of instructions to control the functional elements of the device to perform the described functions. Additionally, or alternatively, the manufacturing system may perform aspects of the described functions using special-purpose hardware.

At 1705, the method may include forming, through a stack of layers that is over a substrate and that includes layers of a first dielectric material and a nitride material, a plurality of dielectric piers each including a second dielectric material based at least in part on depositing respective second dielectric material portions in a plurality of first cavities that each extend through the stack of layers and expose the substrate. The operations of 1705 may be performed in accordance with examples as disclosed herein.

At 1710, the method may include forming a plurality of access lines based at least in part on removing the nitride material from the stack of layers and depositing a first conductive material in a plurality of voids between the layers of the first dielectric material. The operations of 1710 may be performed in accordance with examples as disclosed herein.

At 1715, the method may include forming a plurality of dielectric pillars each including a third dielectric material that surrounds a fourth dielectric material based at least in part on depositing the third dielectric material and the fourth dielectric material in a plurality of second cavities disposed between each of the plurality of dielectric piers. The operations of 1715 may be performed in accordance with examples as disclosed herein.

At 1720, the method may include removing the plurality of dielectric piers, a first portion of the third dielectric material, and a second portion of the third dielectric material opposite the first portion to form a third portion of the third dielectric material and a fourth portion of the third dielectric material positioned opposite the third portion, where the third portion of the third dielectric material, the fourth portion of the third dielectric material, and the fourth dielectric material form a plurality of third cavities that expose the substrate. The operations of 1720 may be performed in accordance with examples as disclosed herein.

At 1725, the method may include forming a plurality of conductive pillars by depositing a second conductive material into the plurality of third cavities, each of the plurality of conductive pillars contacting sidewalls of the third dielectric material and the fourth dielectric material. The operations of 1725 may be performed in accordance with examples as disclosed herein.

At 1730, the method may include forming, after forming the plurality of conductive pillars, a plurality of memory cells based at least in part on depositing a memory material, each of the plurality of memory cells electrically coupled with one conductive pillar of the plurality of conductive pillars and one of the plurality of access lines. The operations of 1730 may be performed in accordance with examples as disclosed herein.

In some examples, an apparatus as described herein may perform a method or methods, such as the method 1700. The apparatus may include features, circuitry, logic, means, or instructions (e.g., a non-transitory computer-readable medium storing instructions executable by a processor), or any combination thereof for performing the following aspects of the present disclosure:

Aspect 17: A method, apparatus, or non-transitory computer-readable medium including operations, features, circuitry, logic, means, or instructions, or any combination thereof for forming, through a stack of layers that is over a substrate and that includes layers of a first dielectric material and a nitride material, a plurality of dielectric piers each including a second dielectric material based at least in part on depositing respective second dielectric material portions in a plurality of first cavities that each extend through the stack of layers and expose the substrate; forming a plurality of access lines based at least in part on removing the nitride material from the stack of layers and depositing a first conductive material in a plurality of voids between the layers of the first dielectric material; forming a plurality of dielectric pillars each including a third dielectric material that surrounds a fourth dielectric material based at least in part on depositing the third dielectric material and the fourth dielectric material in a plurality of second cavities disposed between each of the plurality of dielectric piers; removing the plurality of dielectric piers, a first portion of the third dielectric material, and a second portion of the third dielectric material opposite the first portion to form a third portion of the third dielectric material and a fourth portion of the third dielectric material positioned opposite the third portion, where the third portion of the third dielectric material, the fourth portion of the third dielectric material, and the fourth dielectric material form a plurality of third cavities that expose the substrate; forming a plurality of conductive pillars by depositing a second conductive material into the plurality of third cavities, each of the plurality of conductive pillars contacting sidewalls of the third dielectric material and the fourth dielectric material; and forming, after forming the plurality of conductive pillars, a plurality of memory cells based at least in part on depositing a memory material, each of the plurality of memory cells electrically coupled with one conductive pillar of the plurality of conductive pillars and one of the plurality of access lines.

Aspect 18: The method, apparatus, or non-transitory computer-readable medium of aspect 17, where the third portion of the third dielectric material and the fourth portion of the third dielectric material mechanically couple the fourth dielectric material with sidewalls of the stack of layers after forming the plurality of third cavities.

Aspect 19: The method, apparatus, or non-transitory computer-readable medium of any of aspects 17 through 18, where forming the plurality of dielectric pillars further includes operations, features, circuitry, logic, means, or instructions, or any combination thereof for conformally depositing the third dielectric material on sidewalls of the plurality of second cavities to form a plurality of fourth cavities that are each smaller than the plurality of second cavities and depositing the fourth dielectric material in the plurality of fourth cavities.

Aspect 20: The method, apparatus, or non-transitory computer-readable medium of any of aspects 17 through 19, where forming the plurality of conductive pillars further includes operations, features, circuitry, logic, means, or instructions, or any combination thereof for forming the plurality of conductive pillars including a first conductive pillar and a second conductive pillar that are electrically coupled with a first digit line driver and a third conductive pillar and a fourth conductive pillar that are electrically coupled with a second digit line driver.

Aspect 21: The method, apparatus, or non-transitory computer-readable medium of any of aspects 17 through 20, where forming the plurality of conductive pillars further includes operations, features, circuitry, logic, means, or instructions, or any combination thereof for conformally depositing a third conductive material into the plurality of third cavities; depositing the second conductive material into the plurality of third cavities after conformally depositing the third conductive material; performing a dry etching process to remove portions of the second conductive material; and performing a selective wet etching process to selectively remove portions of the third conductive material from sidewalls of the plurality of third cavities, where each conductive material includes remaining portions of the third conductive material at least partially surrounding the remaining portions of the second conductive material.

Aspect 22: The method, apparatus, or non-transitory computer-readable medium of any of aspects 17 through 21, where forming the plurality of third cavities further includes operations, features, circuitry, logic, means, or instructions, or any combination thereof for performing a first exhumation process to remove the plurality of dielectric piers and performing, after performing the first exhumation process, a second exhumation process to remove the first portion of the third dielectric material and the second portion of the third dielectric material.

Aspect 23: The method, apparatus, or non-transitory computer-readable medium of any of aspects 17 through 22, further including operations, features, circuitry, logic, means, or instructions, or any combination thereof for forming, after forming the plurality of dielectric piers, the plurality of second cavities disposed between each of the plurality of dielectric piers, the plurality of second cavities each extending through the stack of layers and exposing the substrate.

Aspect 24: The method, apparatus, or non-transitory computer-readable medium of aspect 23, further including operations, features, circuitry, logic, means, or instructions, or any combination thereof for forming the plurality of voids between the layers of the first dielectric material based at least in part on removing the layers of the nitride material and forming the plurality of second cavities; depositing the first conductive material into the plurality of voids between the layers of the first dielectric material to form alternating layers of the first dielectric material and the first conductive material; and forming a plurality of second voids between the layers of the first dielectric material based at least in part on removing portions of the first conductive material from each layer of the first conductive material, where each of the plurality of second voids are defined by different layers of the first dielectric material and a sidewall of the first conductive material, and where the plurality of access lines include the first conductive material and are formed based at least in part on forming the plurality of second voids.

Aspect 25: The method, apparatus, or non-transitory computer-readable medium of aspect 24, further including operations, features, circuitry, logic, means, or instructions, or any combination thereof for depositing a fourth conductive material in each of the plurality of second voids, the fourth conductive material in contact with the plurality of access lines; performing a lateral etching process to etch portions of the fourth conductive material to form a plurality of third voids between the layers of the first dielectric material; and depositing a fifth dielectric material in each of the plurality of third voids, the fifth dielectric material electrically coupled with the plurality of access lines via the fourth conductive material, where forming the plurality of conductive pillars occurs after depositing the fifth dielectric material.

Aspect 26: The method, apparatus, or non-transitory computer-readable medium of aspect 25, further including operations, features, circuitry, logic, means, or instructions, or any combination thereof for performing, after forming the plurality of conductive pillars, a second lateral etching process to etch portions of the fifth dielectric material to form a plurality of fourth voids between the layers of the first dielectric material, where each of the plurality of fourth voids are defined by different layers of the first dielectric material, a sidewall of the fifth dielectric material, and a sidewall of one conductive pillar of the plurality of conductive pillars.

Aspect 27: The method, apparatus, or non-transitory computer-readable medium of aspect 26, where forming the plurality of memory cells further includes operations, features, circuitry, logic, means, or instructions, or any combination thereof for depositing the memory material into the plurality of fourth voids.

Aspect 28: The method, apparatus, or non-transitory computer-readable medium of any of aspects 24 through 27, where forming the plurality of voids further includes operations, features, circuitry, logic, means, or instructions, or any combination thereof for performing a wet etching process to selectively remove the nitride material.

Aspect 29: The method, apparatus, or non-transitory computer-readable medium of any of aspects 17 through 28, further including operations, features, circuitry, logic, means, or instructions, or any combination thereof for depositing, after forming the plurality of memory cells, a sixth dielectric material into a plurality of fifth cavities, where the plurality of fifth cavities each extend between two of the plurality of dielectric pillars and are formed based at least in part on depositing the second conductive material into the plurality of third cavities.

Aspect 30: The method, apparatus, or non-transitory computer-readable medium of any of aspects 17 through 29, where forming the plurality of access lines further includes operations, features, circuitry, logic, means, or instructions, or any combination thereof for forming a plurality of first access lines electrically coupled with a first word line driver based at least in part on depositing the first conductive material in voids associated with a first portion of the nitride material and forming a plurality of second access lines electrically coupled with a second word line driver based at least in part on depositing the first conductive material in voids associated with the second portion of the nitride material.

Aspect 31: The method, apparatus, or non-transitory computer-readable medium of any of aspects 17 through 30, where sidewalls of the plurality of second cavities include alternating layers of the first dielectric material and a fifth dielectric material.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 32: An apparatus, including: a plurality of contacts extending through a substrate, where each of the plurality of contacts are associated with a plurality of digit lines; a first plurality of word line plates separated from a second plurality of word line plates by a trench; a plurality of sets of pillars each including a first pillar and a second pillar electrically coupled with the first plurality of word line plates and a third pillar and a fourth pillar electrically coupled with the second plurality of word line plates, where each first pillar and third pillar are electrically coupled with one digit line of the plurality of digit lines and each second pillar and fourth pillar are electrically coupled with another digit line of the plurality of digit lines; a dielectric material positioned between each set of the plurality of sets of pillars, the dielectric material in contact with the second pillar and the fourth pillar of a first set of pillars and the first pillar and the third pillar of a second set of pillars; and a plurality of storage elements including memory material and electrically coupled with a word line plate of the first plurality of word line plates and the second plurality of word line plates and with a pillar in the plurality of sets of pillars.

Aspect 33: The apparatus of aspect 32, further including: a plurality of dielectric pillars positioned between each first pillar, second pillar, third pillar, and fourth pillar of the plurality of sets of pillars.

Aspect 34: The apparatus of any of aspects 32 through 33, where the plurality of storage elements further include: a plurality of first storage elements in contact with the first pillar in each of the plurality of sets of pillars; a plurality of second storage elements in contact with the second pillar in each of the plurality of sets of pillars; a plurality of third storage elements in contact with the third pillar in each of the plurality of sets of pillars; and a plurality of fourth storage elements in contact with the fourth pillar in each of the plurality of sets of pillars.

An apparatus is described. The following provides an overview of aspects of the apparatus as described herein:

Aspect 35: An apparatus having a memory array formed by a process including: forming, through a stack of layers that is over a substrate, a trench to expose the substrate, the stack of layers including layers of a first dielectric material and a nitride material; forming, along the trench, a plurality of dielectric piers each including a second dielectric material based at least in part on depositing respective second dielectric material portions in the trench; forming a plurality of access lines based at least in part on removing the nitride material from the stack of layers and depositing a first conductive material in a plurality of voids between the layers of the first dielectric material; forming, along the trench, a plurality of dielectric pillars each including a third dielectric material that surrounds a fourth dielectric material based at least in part on depositing the third dielectric material and the fourth dielectric material in a plurality of first cavities disposed between each of the plurality of dielectric piers; removing the plurality of dielectric piers, a first portion of the third dielectric material, and a second portion of the third dielectric material opposite the first portion to form a third portion of the third dielectric material and a fourth portion of the third dielectric material positioned opposite the third portion, where the third portion of the third dielectric material, the fourth portion of the third dielectric material, and the fourth dielectric material form a plurality of second cavities that expose the substrate; forming a plurality of conductive pillars along the trench by depositing a second conductive material into the plurality of second cavities, each of the plurality of conductive pillars contacting sidewalls of the third dielectric material and the fourth dielectric material; and forming, after forming the plurality of conductive pillars, a plurality of memory cells based at least in part on depositing a memory material, each of the plurality of memory cells electrically coupled with one conductive pillar of the plurality of conductive pillars and one of the plurality of access lines.

It should be noted that the methods described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
forming, through a stack of layers over a substrate, a trench to expose the substrate, the stack of layers comprising layers of a first dielectric material and a nitride material;
forming, along the trench, a plurality of dielectric piers each comprising a second dielectric material based at least in part on depositing respective second dielectric material portions in the trench;
forming a plurality of access lines based at least in part on removing the nitride material from the stack of layers and depositing a first conductive material in a plurality of voids between the layers of the first dielectric material;
forming, along the trench, a plurality of dielectric pillars each comprising a third dielectric material that surrounds a fourth dielectric material based at least in part on depositing the third dielectric material and the fourth dielectric material in a plurality of first cavities disposed between each of the plurality of dielectric piers;
removing the plurality of dielectric piers, a first portion of the third dielectric material, and a second portion of the third dielectric material opposite the first portion to form a third portion of the third dielectric material and a fourth portion of the third dielectric material positioned opposite the third portion, wherein the third portion of the third dielectric material, the fourth portion of the third dielectric material, and the fourth dielectric material form a plurality of second cavities that expose the substrate;
forming a plurality of conductive pillars along the trench by depositing a second conductive material into the plurality of second cavities, each of the plurality of conductive pillars contacting sidewalls of the third dielectric material and the fourth dielectric material; and
forming, after forming the plurality of conductive pillars, a plurality of memory cells based at least in part on depositing a memory material, each of the plurality of memory cells electrically coupled with one conductive pillar of the plurality of conductive pillars and one of the plurality of access lines.

2. The method of claim 1, wherein the third portion of the third dielectric material and the fourth portion of the third dielectric material mechanically couple the fourth dielectric material with sidewalls of the trench after forming the plurality of second cavities.

3. The method of claim 1, wherein forming the plurality of dielectric pillars further comprises:
conformally depositing the third dielectric material on sidewalls of the plurality of first cavities to form a plurality of third cavities that are each smaller than the plurality of first cavities; and
depositing the fourth dielectric material in the plurality of third cavities.

4. The method of claim 1, wherein forming the plurality of conductive pillars further comprises:
forming the plurality of conductive pillars comprising a first conductive pillar and a second conductive pillar that are electrically coupled with a first digit line driver and a third conductive pillar and a fourth conductive pillar that are electrically coupled with a second digit line driver.

5. The method of claim 1, wherein forming the plurality of conductive pillars further comprises:
conformally depositing a third conductive material into the plurality of second cavities;
depositing the second conductive material into the plurality of second cavities after conformally depositing the third conductive material;
performing a dry etching process to remove portions of the second conductive material; and
performing a selective wet etching process to selectively remove portions of the third conductive material from sidewalls of the plurality of second cavities, wherein each conductive material comprises remaining portions of the third conductive material at least partially surrounding the remaining portions of the second conductive material.

6. The method of claim 1, wherein forming the plurality of second cavities further comprises:
performing a first exhumation process to remove the plurality of dielectric piers; and
performing, after performing the first exhumation process, a second exhumation process to remove the first portion of the third dielectric material and the second portion of the third dielectric material.

7. The method of claim 1, further comprising:
forming the plurality of voids between the layers of the first dielectric material based at least in part on removing the layers of the nitride material and removing a second nitride material from the trench after forming the plurality of dielectric piers;
depositing the first conductive material into the plurality of voids between the layers of the first dielectric material to form alternating layers of the first dielectric material and the first conductive material; and
forming a plurality of second voids between the layers of the first dielectric material based at least in part on removing portions of the first conductive material from each layer of the first conductive material, wherein each of the plurality of second voids are defined by different layers of the first dielectric material and a sidewall of the first conductive material, and wherein the plurality of access lines comprise the first conductive material and are formed based at least in part on forming the plurality of second voids.

8. The method of claim 7, further comprising:
depositing a fourth conductive material in each of the plurality of second voids, the fourth conductive material in contact with the plurality of access lines;
performing a lateral etching process to etch portions of the fourth conductive material to form a plurality of third voids between the layers of the first dielectric material; and
depositing a fifth dielectric material in each of the plurality of third voids, the fifth dielectric material electrically coupled with the plurality of access lines via the fourth conductive material, wherein forming the plurality of conductive pillars occurs after depositing the fifth dielectric material.

9. The method of claim 8, further comprising:
performing, after forming the plurality of conductive pillars, a second lateral etching process to etch portions of the fifth dielectric material to form a plurality of fourth voids between the layers of the first dielectric material, wherein each of the plurality of fourth voids are defined by different layers of the first dielectric material, a sidewall of the fifth dielectric material, and a sidewall of one conductive pillar of the plurality of conductive pillars.

10. The method of claim 9, wherein forming the plurality of memory cells further comprises:
depositing the memory material into the plurality of fourth voids.

11. The method of claim 7, wherein forming the plurality of voids further comprises:
performing a wet etching process to selectively remove the nitride material and the second nitride material.

12. The method of claim 1, further comprising:
depositing, after forming the plurality of memory cells, a sixth dielectric material into a plurality of fourth cavities, wherein the plurality of fourth cavities each extend between two of the plurality of dielectric pillars and are formed based at least in part on depositing the second conductive material into the plurality of second cavities.

13. The method of claim 1, wherein:
forming the trench divides each layer of the nitride material into a first portion associated with a first word line driver and a second portion associated with a second word line driver;
forming the plurality of access lines further comprises:
forming a plurality of first access lines electrically coupled with the first word line driver based at least in part on depositing the first conductive material in voids associated with the first portion of the nitride material, and
forming a plurality of second access lines electrically coupled with the second word line driver based at least in part on depositing the first conductive material in voids associated with the second portion of the nitride material.

14. The method of claim 1, wherein sidewalls of the plurality of first cavities comprise alternating layers of the first dielectric material and a fifth dielectric material.

15. The method of claim 1, further comprising:
depositing a second nitride material into the trench; and
forming a plurality of fifth cavities each extending through the second nitride material, portions of the first dielectric material, and portions of the nitride material to expose the substrate, wherein forming the plurality of dielectric piers comprises depositing the respective second dielectric material portions into the plurality of fifth cavities.

16. The method of claim 15, wherein:
forming each fifth cavity of the plurality of fifth cavities exposes a respective first sidewall of the stack of layers on a first side of each fifth cavity and a respective second sidewall of the stack of layers on a second side of each fifth cavity; and
forming the plurality of dielectric piers comprises depositing, in each fifth cavity, the respective second dielectric material portion in contact with the respective first sidewall and the respective second sidewall.

17. An apparatus, comprising:
a plurality of contacts extending through a substrate, wherein each of the plurality of contacts are associated with a plurality of digit lines;
a first plurality of word line plates separated from a second plurality of word line plates by a trench;
a plurality of sets of pillars each comprising a first pillar and a second pillar electrically coupled with the first plurality of word line plates and a third pillar and a fourth pillar electrically coupled with the second plurality of word line plates, wherein each first pillar and third pillar are electrically coupled with one digit line of the plurality of digit lines and each second pillar and fourth pillar are electrically coupled with another digit line of the plurality of digit lines;
a dielectric material positioned between each set of the plurality of sets of pillars, the dielectric material in contact with the second pillar and the fourth pillar of a first set of pillars and the first pillar and the third pillar of a second set of pillars; and
a plurality of storage elements comprising memory material and electrically coupled with a word line plate of the first plurality of word line plates and the second plurality of word line plates and with a pillar in the plurality of sets of pillars.

18. The apparatus of claim 17, further comprising:
a plurality of dielectric pillars positioned between each first pillar, second pillar, third pillar, and fourth pillar of the plurality of sets of pillars.

19. The apparatus of claim 17, wherein the plurality of storage elements further comprise:
a plurality of first storage elements in contact with the first pillar in each of the plurality of sets of pillars;
a plurality of second storage elements in contact with the second pillar in each of the plurality of sets of pillars;
a plurality of third storage elements in contact with the third pillar in each of the plurality of sets of pillars; and
a plurality of fourth storage elements in contact with the fourth pillar in each of the plurality of sets of pillars.

20. An apparatus having a memory array formed by a process comprising:
forming, through a stack of layers that is over a substrate, a trench to expose the substrate, the stack of layers comprising layers of a first dielectric material and a nitride material;
forming, along the trench, a plurality of dielectric piers each comprising a second dielectric material based at least in part on depositing respective second dielectric material portions in the trench;
forming a plurality of access lines based at least in part on removing the nitride material from the stack of layers and depositing a first conductive material in a plurality of voids between the layers of the first dielectric material;
forming, along the trench, a plurality of dielectric pillars each comprising a third dielectric material that surrounds a fourth dielectric material based at least in part on depositing the third dielectric material and the fourth dielectric material in a plurality of first cavities disposed between each of the plurality of dielectric piers;
removing the plurality of dielectric piers, a first portion of the third dielectric material, and a second portion of the third dielectric material opposite the first portion to form a third portion of the third dielectric material and a fourth portion of the third dielectric material positioned opposite the third portion, wherein the third portion of the third dielectric material, the fourth portion of the third dielectric material, and the fourth dielectric material form a plurality of second cavities that expose the substrate;
forming a plurality of conductive pillars along the trench by depositing a second conductive material into the plurality of second cavities, each of the plurality of conductive pillars contacting sidewalls of the third dielectric material and the fourth dielectric material; and
forming, after forming the plurality of conductive pillars, a plurality of memory cells based at least in part on depositing a memory material, each of the plurality of memory cells electrically coupled with one conductive pillar of the plurality of conductive pillars and one of the plurality of access lines.
